(19) United States
(12) Patent Application Publication
(10) Pub. No.: US 2025/0040125 A1
(43) Pub. Date: Jan. 30, 2025

(54) SEMICONDUCTOR STRUCTURE AND FABRICATION METHOD THEREOF AND MEMORY SYSTEM

(71) Applicant: Yangtze Memory Technologies Co., Ltd., Wuhan (CN)

(72) Inventors: Zhaoyun TANG, Wuhan (CN); Zongliang HUO, Wuhan (CN); Wenbin ZHOU, Wuhan (CN)

(21) Appl. No.: 18/513,260

(22) Filed: Nov. 17, 2023

(30) Foreign Application Priority Data
Jul. 25, 2023 (CN) 202310921509.9

(51) Int. Cl. H10B 12/00; H01L 21/762; H01L 29/423

(52) U.S. Cl. CPC H10B 12/395; H01L 21/76229; H01L 29/4236; H10B 12/0387; H10B 12/315; H10B 12/50

(57) ABSTRACT

Semiconductor structures, fabrication methods thereof, and memory systems are provided. In one aspect, a method of forming a semiconductor structure includes: forming a plurality of first trenches in a semiconductor base from a surface of the semiconductor base, forming a plurality of gate structures in the plurality of first trenches, forming a plurality of second trenches in the semiconductor base, and forming a plurality of isolation structures in the plurality of second trenches. The plurality of first trenches extend along a first direction. Each of the plurality of second trenches is between two adjacent trenches of the plurality of first trenches, and the plurality of second trenches extend along the first direction.

### CROSS-REFERENCE TO RELATED APPLICATIONS

The present application claims the benefit of priority to Chinese Patent Application No. 202310921509.9, filed on Jul. 25, 2023, the content of which is incorporated herein by reference in its entirety.

### TECHNICAL FIELD

The present disclosure relates to the technical field of semiconductor chips, and particularly to a semiconductor structure and a fabrication method thereof, and a memory system.

### BACKGROUND

Planar memory cells are scaled to smaller sizes by the improvement of process technologies, circuit designs, programming algorithms, and manufacturing processes. However, as feature sizes of the memory cells approach a lower limit, the planar processes and manufacturing technologies become challenging and costly. As a result, the memory density for the planar memory cells approaches an upper limit.

A three-dimensional (3D) memory architecture can address density limitations in the planar memory cells. The 3D memory architecture comprises a memory array and a peripheral circuit used to facilitate operation of the memory array.

### SUMMARY

Examples of the present disclosure provide a semiconductor structure and a fabrication method thereof, and a memory system, in order to solve the problem of complexity and difficulty in semiconductor structure fabrication processes in the related technology.

In order to achieve the above objectives, the examples of the present disclosure employ the following technical solutions:

In an aspect, a fabrication method of a semiconductor structure is provided, comprising: forming a plurality of first trenches in a semiconductor base, e.g., from a first surface of the semiconductor base, where the first trenches extend along a first direction; forming a plurality of gate structures in the plurality of first trenches; forming a plurality of second trenches in the semiconductor base, e.g., from the first surface of the semiconductor base, where each of the second trenches is located between two adjacent ones of the first trenches, and the second trenches extend along the first direction; and forming a plurality of isolation structures in the plurality of second trenches.

The fabrication method of the semiconductor structure provided by the present disclosure may improve the problem that the semiconductor structure is prone to bend by filling the first trenches with an insulation material before forming the second trenches. Due to the formation of the second trenches and the formation of the isolation structures in the second trenches, a larger number of semiconductor pillars may be formed, thereby increasing transistor density in the semiconductor structure. Furthermore, since the semiconductor structure may be a memory or a portion in a memory, it is also favorable to increase storage density of the memory. Moreover, in some examples, the second trenches are formed by a self-aligned approach, so that the fabrication method also improves the process window, increases the overlay margin, and reduces the process difficulty and cost.

In some examples, before the forming the plurality of first trenches in the semiconductor base, the fabrication method further comprises: disposing a mask layer on a first surface of the semiconductor base, where the mask layer comprises a plurality of openings; and the forming the plurality of first trenches on the first surface of the semiconductor base comprises: etching the semiconductor base by means of the plurality of openings of the mask layer, so as to form the plurality of first trenches.

In some examples, after the forming the plurality of gate structures in the plurality of first trenches and before the forming the plurality of second trenches from the first surface of the semiconductor base, the fabrication method further comprises: forming a plurality of insulation filling structures, wherein each of the insulation filling structures is located within one of the first trenches and one of the openings that are connected together, and a portion of the insulation filling structure located within the opening is defined as a first portion; at least removing a first sublayer located between two adjacent ones of the insulation filling structures, wherein the first sublayer is at least a part of the mask layer; forming an isolation layer that covers the plurality of insulation filling structures and the first surface; and etching the semiconductor structure along a target direction using a first etching process, so as to form a plurality of barrier portions and a plurality of third trenches, wherein the target direction points from a side of the semiconductor base facing the isolation layer to a side of the semiconductor base facing away from the isolation layer; each of the barrier portions comprises at least a part of the first portion and the isolation layer around the first portion that is not etched off by the first etching process; each of the third trenches is located between two adjacent ones of the barrier portions, and the third trenches expose the first surface; and the forming the plurality of second trenches from the first surface of the semiconductor base comprises: etching the semiconductor base along the target direction by the plurality of third trenches using a second etching process, so as to form the plurality of second trenches.

In some examples, the first etching process and the second etching process each comprises a dry etching process.

In some examples, the forming the isolation layer comprises: forming a first dielectric layer and a second dielectric layer sequentially, wherein a material of the first dielectric layer is different from a material of the second dielectric layer.

In some examples, the material of the first dielectric layer comprises silicon nitride, and the material of the second dielectric layer comprises oxide.

In some examples, the disposing the mask layer on the first surface of the semiconductor base comprises: forming the first sublayer on the first surface of the semiconductor base, wherein a material of the first sublayer includes oxide or silicon nitride.

In some examples, the disposing the mask layer on the first surface of the semiconductor base comprises: forming a second sublayer and the first sublayer sequentially on the first surface of the semiconductor base, wherein a material of the first sublayer is different from a material of the second sublayer.

In some examples, the material of the first sublayer comprises silicon nitride, and the material of the second sublayer comprises oxide.

In some examples, the disposing the mask layer on the first surface of the semiconductor base further comprises: forming a third sublayer and a fourth sublayer sequentially on the first sublayer, wherein the material of the first sublayer is the same as a material of the fourth sublayer, the material of the first sublayer is different from a material of the third sublayer, and the third sublayer serves as a stop layer during removal of the fourth sublayer.

In some examples, the material of the third sublayer includes polysilicon or titanium nitride, and the material of the fourth sublayer includes silicon nitride.

In some examples, the disposing the mask layer on the first surface of the semiconductor base further comprises: forming a fifth sublayer and a sixth sublayer sequentially on the second sublayer, wherein the fifth sublayer and the sixth sublayer are located between the second sublayer and the first sublayer; the material of the second sublayer is the same as a material of the sixth sublayer, the material of the second sublayer is different from a material of the fifth sublayer; and the fifth sublayer serves as a stop layer during removal of the sixth sublayer.

In some examples, the material of the fifth sublayer includes silicon nitride, and the material of the sixth sublayer includes oxide.

In some examples, after the forming the plurality of first trenches in the semiconductor base and before the forming the plurality of gate structures in the plurality of first trenches, the fabrication method further comprises: forming a first insulation layer on inner walls of the first trenches, wherein first sub-trenches are formed as being surrounded within the first insulation layer; and forming stop blocks at bottoms of the first sub-trenches to obtain second sub-trenches; and the forming the plurality of gate structures in the plurality of first trenches comprises: forming a gate layer on sidewalls of the second sub-trenches, wherein a spacing is left between the gate layer and the first surface.

In some examples, the forming the plurality of gate structures in the plurality of first trenches further comprises: performing oxidation treatment on the sidewalls of the second sub-trenches to form a gate insulation layer.

In some examples, the forming the plurality of isolation structures in the plurality of second trenches comprises: forming a second insulation layer on inner walls of the second trenches, wherein accommodation trenches are formed as being surrounded within the second insulation layer; forming isolation pillars in the accommodation trenches; and filling the accommodation trenches with an insulation material to cover the isolation pillars.

In some examples, the forming the plurality of isolation structures in the plurality of second trenches comprises: filling the second trenches with an insulation material to form the isolation structures comprising air gaps.

In another aspect, a semiconductor structure is provided, comprising: a plurality of gate filling structures, a plurality of isolation structures, and a plurality of semiconductor pillars. The plurality of gate filling structures extend along a first direction. Each of the isolation structures is located between two adjacent ones of the gate filling structures, the isolation structures extend along the first direction, and an arrangement direction of the isolation structures and the gate filling structures is a second direction. Each of the semiconductor pillars is located between the isolation structure and the gate filling structure, the semiconductor pillars extend along a third direction that intersects a first reference plane, and the first direction and the second direction are in the first reference plane, wherein a length of the isolation structure along the first direction is less than a length of the gate filling structure along the first direction.

In this example, a plurality of semiconductor pillars may be disposed between the isolation structure and the gate filling structures on two sides of the isolation structure, thereby forming a plurality of vertical transistors, which is favorable to increase storage density of the semiconductor structure. Moreover, the length of the isolation structure along the first direction is less than the length of the gate filling structure along the first direction, such that the length of the isolation structure is short. For example, the isolation structure may not extend to an edge area (such as an ineffective storage area), which is favorable to reduce cost during the fabrication of the semiconductor structure.

In some examples, the first direction and the third direction are in a second reference plane; an orthographic projection of the isolation structure on the second reference plane is a first orthographic projection, and an orthographic projection of the gate filling structure on the second reference plane is a second orthographic projection; and two ends of the first orthographic projection are located between two ends of the second orthographic projection along the first direction.

In some examples, the semiconductor structure has a core area and an edge area; the gate filling structure is located in the core area and the edge area; and the isolation structure is located in the core area.

In some examples, distances between the isolation structure and two adjacent gate filling structures are equal along the second direction.

In some examples, a difference in the distances between the isolation structure and the two adjacent gate filling structures along the second direction is less than or equal to 10 nm.

In some examples, the gate filling structure comprises a stop structure and a gate structure that are stacked along the third direction, wherein the stop structure comprises a stop block and a first insulation layer that is located between the stop block and the semiconductor pillar, and the gate structure comprises a gate layer and a gate insulation layer that is located between the gate layer and the semiconductor pillar; and distances between the isolation structure and the gate insulation layers in the two adjacent gate filling structures are equal along the second direction.

In some examples, the semiconductor pillar comprises a channel portion, a first electrode, and a second electrode; the channel portion is located between the first electrode and the second electrode along the third direction; and the channel portion overlaps the gate layer along the second direction; and a storage unit is electrically connected with the first electrode.

In yet another aspect, a memory system is provided, comprising: a semiconductor structure fabricated by the fabrication method of any one of the above examples, or the semiconductor structure of any one of the above examples; and a controller coupled to the semiconductor structure.

It can be understood that, the advantageous effects that can be achieved by the memory system provided by the above example of the present disclosure may be referred to the advantageous effects of the semiconductor structure and the fabrication method thereof above, which are no longer repeated here.

### BRIEF DESCRIPTION OF THE DRAWINGS

In order to illustrate the technical solutions in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limitations on actual size of product, actual flow of method, actual timing of signal, etc. involved in the examples of the present disclosure.

FIG. 1 is a structural block diagram of an electronic apparatus provided by some examples of the present disclosure;

FIG. 2 is a structural block diagram of a memory in some examples of the present disclosure;

FIG. 3 is a structural diagram of a memory cell in some examples of the present disclosure;

FIG. 4A is a flow diagram of a fabrication method of a semiconductor structure provided by some examples of the present disclosure;

FIG. 4B is a flow diagram of another fabrication method of a semiconductor structure provided by some examples of the present disclosure;

FIG. 4C is a flow diagram of yet another fabrication method of a semiconductor structure provided by some examples of the present disclosure;

FIG. 4D is a flow diagram of still another fabrication method of a semiconductor structure provided by some examples of the present disclosure;

FIGS. 5A-5K are structural diagrams corresponding to some steps in a fabrication method of a semiconductor structure provided by some examples of the present disclosure;

FIGS. 6A-6C are structural diagrams corresponding to some steps in a fabrication method of a semiconductor structure provided by some examples of the present disclosure;

FIGS. 7A-7D are structural diagrams corresponding to some steps in a fabrication method of a semiconductor structure provided by some examples of the present disclosure;

FIG. 8 is a top view of a semiconductor structure in some examples of the present disclosure;

FIG. 9 is a projection view of an isolation structure and a gate filling structure in some examples of the present disclosure; and

FIG. 10 is a structural diagram of a memory in some examples of the present disclosure.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure shall fall in the scope of protection of the present disclosure.

In the description of the present disclosure, it is to be understood that the terms “center”, “upper”, “lower”, “front”, “rear”, “left”, “right”, “vertical”, “horizontal”, “top”, “bottom”, “inner”, “outer”, etc. indicate orientations or position relationships that are based on the orientations or position relationships as shown in the drawings, and are only intended to facilitate description of the present disclosure and to simplify the description, instead of indicating or implying that a device or an element indicated must have a specific orientation or be constructed and operated in a specific orientation, and thus cannot be understood as limitations on the present disclosure.

Unless otherwise specified in the context, throughout the specification and the claims, the term “comprise” is interpreted as an open and inclusive meaning, i.e., “including, but not limited to”. In the description of the specification, the terms “one example”, “some examples”, “an example”, “in an example”, or “some examples” indicate that particular features, structures, materials, or characteristics related to the example are included in at least one example of the present disclosure. The schematic representation of the above terms may not necessarily refer to the same example. Furthermore, these particular features, structures, materials, or characteristics may be included in one or more examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly include one or more of such features. In the description of the examples of the present disclosure, “a plurality of” means two or more, unless otherwise stated.

In describing some examples, expressions of “coupled” and “connected” and derivatives thereof may be used. For example, the term “connected” may be used in the description of some examples to indicate that two or more components have a direct physical contact or electrical contact with each other. For another example, the term “coupled” may be used in the description of some examples to indicate that two or more components have a direct physical contact or electrical contact. However, the term “coupled” may also mean that two or more components have no direct contact with each other, but still cooperate or interact with each other. The examples disclosed here are not necessarily limited to the content herein.

“At least one of A, B and C” and “at least one of A, B or C” have the same meaning, both including the following combinations of A, B and C: A alone, B along, C alone, a combination of A and B, a combination of A and C, a combination of B and C, and a combination of A, B and C.

“A and/or B” includes the following three combinations: A alone, B alone, and a combination of A and B.

The use of “suitable for” or “configured to” herein implies open and inclusive language, and does not exclude an apparatus suitable for performing or configured to perform additional tasks or steps.

In addition, the use of “based on” implies openness and inclusiveness, as processes, operations, calculations, or other actions “based on” one or more of the described conditions or values may be based on an additional condition or exceed the described value in practice.

The meaning of “on”, “above”, and “over” in the contents of the present disclosure should be interpreted in the broadest manner such that “on” not only implies “directly on something” but also includes the meaning of “on something” with an intermediate feature or layer therebetween, and that “above” or “over” not only implies “above” or “over” something but also includes the meaning of “above” or “over” something with no intermediate feature or layer therebetween (i.e., directly on something).

Example implementations are described herein with reference to at least one of a cross-sectional view or a planar view that are used as idealized example drawings. In the drawings, thicknesses of a layer and a region are exaggerated for clarity. Thus, changes in shapes relative to the drawings caused by, for example, manufacturing technology and/or tolerance, may be conceived. Therefore, the example implementations should not be interpreted as being limited to the shapes of regions shown herein, but rather include shape deviations caused by, for example, manufacturing. For example, an etching region shown as a rectangle will typically have a curved feature. Therefore, the regions shown in the drawings are essentially schematic, and their shapes are neither intended to show actual shapes of regions of an apparatus, nor intended to limit the scope of the example implementations.

As used herein, the term “substrate” refers to a material onto which subsequent material layers may be added. The substrate itself can be patterned. Materials added onto the substrate can be patterned or can remain unpatterned. Furthermore, the substrate may include a variety of semiconductor materials, such as silicon, germanium, gallium arsenide, indium phosphide, etc. Alternatively, the substrate can be made from an electrically non-conductive material, such as glass, plastic, or sapphire wafers, etc.

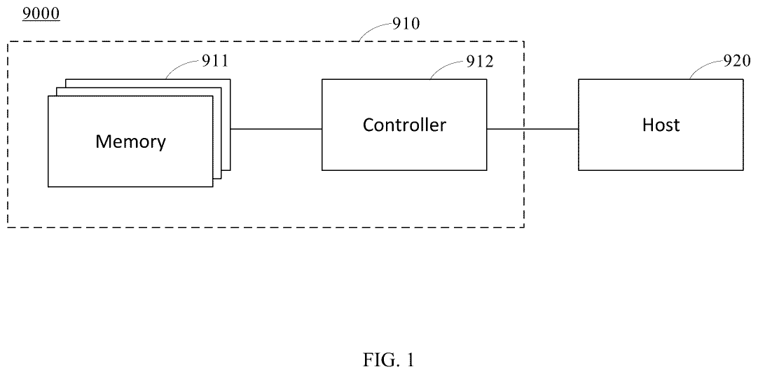

FIG. 1 is a structural block diagram of an electronic apparatus 9000 provided by some examples of the present disclosure. The electronic apparatus 9000 may be a mobile phone, a desktop computer, a laptop computer, a tablet, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein. As shown in FIG. 1, the electronic apparatus 9000 may comprise a memory system 910 and a host 920, wherein the memory system 910 may have one or more memories 911 and a controller 912. The host 920 may be a processor (e.g., a central processing unit (CPU)) or a system-on-chip (SoC) (e.g., an application processor (AP)) of the electronic apparatus 9000. The host 920 may be configured to send or receive data to or from the memory 911.

The controller 912 is coupled to the memory 911 and the host 920 and is configured to control the memory 911. The number of the memory 911 may be one or more. In FIG. 1, three memories 911 are used as an example for illustration. The controller 912 can manage data stored in each of the memories 911 and communicate with the host 920. The controller 912 may be configured to control operations of each of the memories 911, such as read, write, and refresh operations. The controller 912 may be further configured to manage various functions with respect to data stored or to be stored in each of the memories 911, including, but not limited to, refresh and timing control, command/request translation, buffering and scheduling, and power management. In some implementations, the controller 912 is also configured to determine the maximum memory capacity available to a computer system, the number of memory banks, the memory type and speed, memory chip data depth and data width, and other important parameters. Any other suitable functions may be also performed by the controller 912. The controller 912 may communicate with an external apparatus (e.g., the host 920) according to a particular communication protocol. For example, the controller 912 may communicate with the external apparatus through at least one of various interface protocols, such as a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, a Firewire protocol, etc.

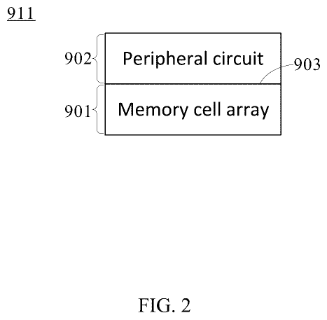

FIG. 2 is a structural block diagram of a memory in some examples of the present disclosure. As shown in FIG. 2, the memory 911 comprises a memory cell array and a peripheral circuit configured to control the memory cell array. The peripheral circuit (also referred to as a control and sense circuit) may include any of at least one of suitable digital, analog or hybrid signal circuits used to facilitate operations of the memory cell array. For example, the peripheral circuit may comprise one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, and any portion (e.g., a sub-circuit) of the above-mentioned functional circuits, or any active or passive components (e.g., a transistor, a diode, a resistor, or a capacitor) of the circuits. In an example, the peripheral circuit may use a complementary metal-oxide-semiconductor (CMOS) technology. For example, the peripheral circuit may be implemented using a logical process (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.).

The memory cell array and the peripheral circuit may be arranged side by side in the same plane, e.g., on the same wafer, that is, the memory cell array and the peripheral circuit may be located in the same semiconductor structure. The memory cell array and the peripheral circuit may be also formed on different wafers and bonded together in a face-to-face manner. As shown in FIG. 2, when the memory cell array and the peripheral circuit are formed on different wafers and bonded together in a face-to-face manner, the memory 911 may comprise a first semiconductor structure 901 and a second semiconductor structure 902, and a bonding interface 903 between the first semiconductor structure 901 and the second semiconductor structure 902 (in a vertical direction, e.g., a Y direction in FIG. 2). The first semiconductor structure 901 may comprise the memory cell array, and the second semiconductor structure 902 may comprise the peripheral circuit. A large number of interconnections (e.g., bonding contacts) are formed through the bonding interface 903, such that a direct short-distance (e.g., micron-scale) electrical connection can be carried out between the first semiconductor structure 901 and the second semiconductor structure 902, rather than a long-distance (e.g., millimeter- or centimeter-scale) chip-to-chip data bus on a circuit board, e.g., a printed circuit board (PCB). As such, chip interface delay is eliminated, and high-speed I/O throughput is achieved with reduced power consumption. Data transfer between the memory cell array in the first semiconductor structure 901 and the peripheral circuit in the second semiconductor structure 902 can be performed through the interconnections (e.g., the bonding contacts) passing through the bonding interface 903. By vertically integrating the first semiconductor structure 901 and the second semiconductor structure 902, the chip size can be reduced, and storage density of the memory 911 can be increased.

The memory cell array may be an array of memory cells that use vertical transistors as switches and select devices. In some implementations, the memory cell array may be a DRAM cell array. For ease of description, the DRAM cell array may be used as an example to describe the memory cell array in the present disclosure. However, it is to be understood that the memory cell array is not limited to the DRAM cell array. For example, the memory cell array may also include any other suitable types of memory cell arrays that can use vertical transistors as switches and select devices, such as a PCM cell array, a static random-access memory (SRAM) cell array, a FRAM cell array, a resistive memory cell array, a magnetic memory cell array, a spin transfer torque (STT) memory cell array, etc.

When the memory cell array is a DRAM cell array, the memory cell therein is a DRAM cell. The DRAM cell comprises a capacitor used to store data bits as positive or negative charges, and one or more transistors (also referred to as transfer transistors) that control (e.g., switch and select) an access to the DRAM cell. In some implementations, each DRAM cell is a one-transistor one-capacitor (1T1C) cell. According to some implementations, the DRAM cell can be refreshed by the peripheral circuit to maintain data.

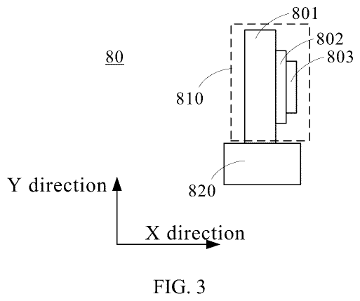

FIG. 3 is a structural diagram of a memory cell in some examples of the present disclosure. As shown in FIG. 3, the memory cell 80 comprises a vertical transistor 810 and a storage unit 820 coupled to the vertical transistor 810. The vertical transistor 810 comprises a semiconductor pillar 801, a gate insulation layer 802, and a gate layer 803. Two ends of the semiconductor pillar 801 along a Y direction are a source and a drain respectively, and one of the source and the drain is coupled with the storage unit 820. In some implementations, the memory cell 80 is a DRAM cell, and the storage unit 820 is a capacitor used to store charges as binary information stored by a corresponding DRAM cell. In some implementations, the memory cell 80 is a PCM cell, and the storage unit 820 is a PCM element (e.g., comprising a chalcogenide alloy) used to store binary information of a corresponding PCM cell based on different resistivities of the PCM element in an amorphous phase and a crystalline phase. In some implementations, the memory cell 80 is a FRAM cell array, and the storage unit 820 is a ferroelectric capacitor used to store binary information of a corresponding FRAM cell based on switching between two polarization states of a ferroelectric material under an external electric field.

Memory cells 80 may be arranged in a two-dimensional (2D) array with rows and columns. The memory 911 may comprise word lines that couple the peripheral circuit with the memory cell array to control the turning on and off of the vertical transistors 810 in the memory cells 80 in the rows, and bit lines that couple the peripheral circuit with the memory cell array to send data to and/or receive data from the memory cells 80 in the columns. That is, each word line may be coupled to the memory cells 80 of a corresponding row, and each bit line may be coupled to the memory cells 80 of a corresponding column.

Some examples of the present disclosure provide a semiconductor structure 100 and a fabrication method thereof. The semiconductor structure 100 may be the aforementioned memory 911 or a portion (e.g., the first semiconductor structure 901) of the aforementioned memory 911. The semiconductor structure 100 may be coupled with the controller 912 when the semiconductor structure 100 is applied to the memory system 910.

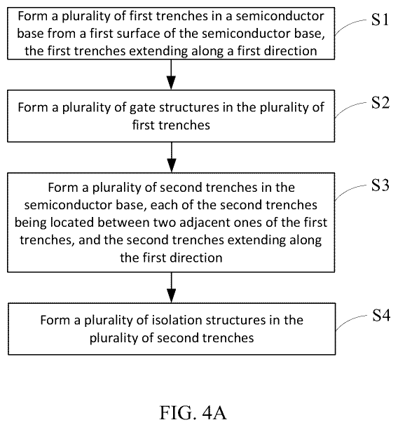

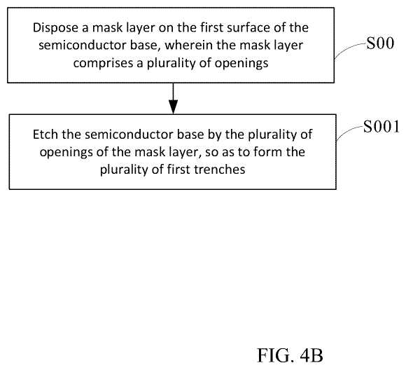

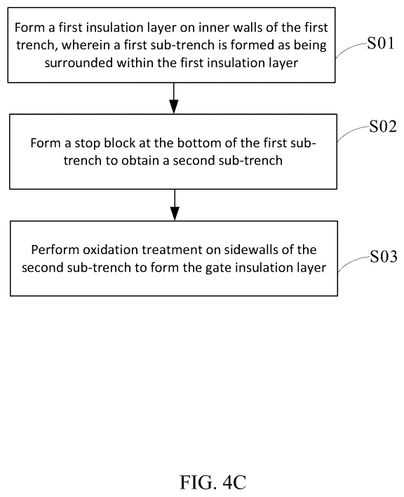

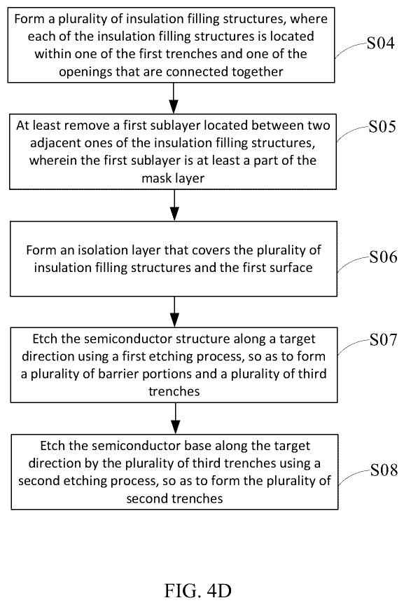

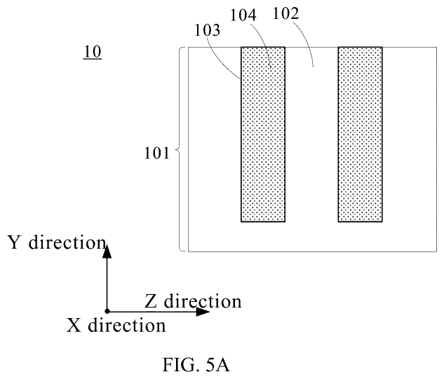

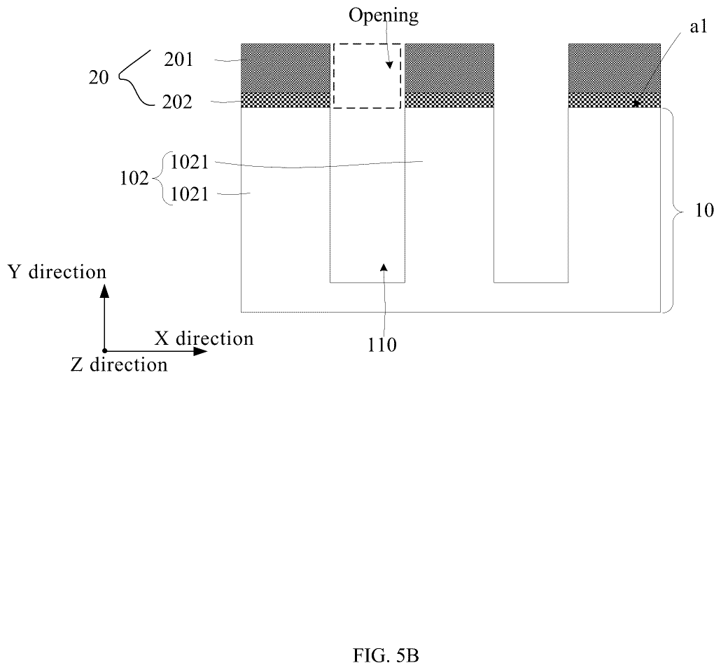

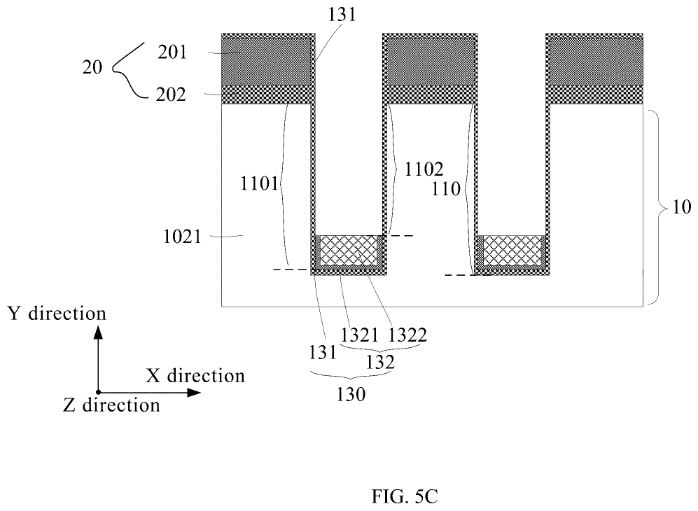

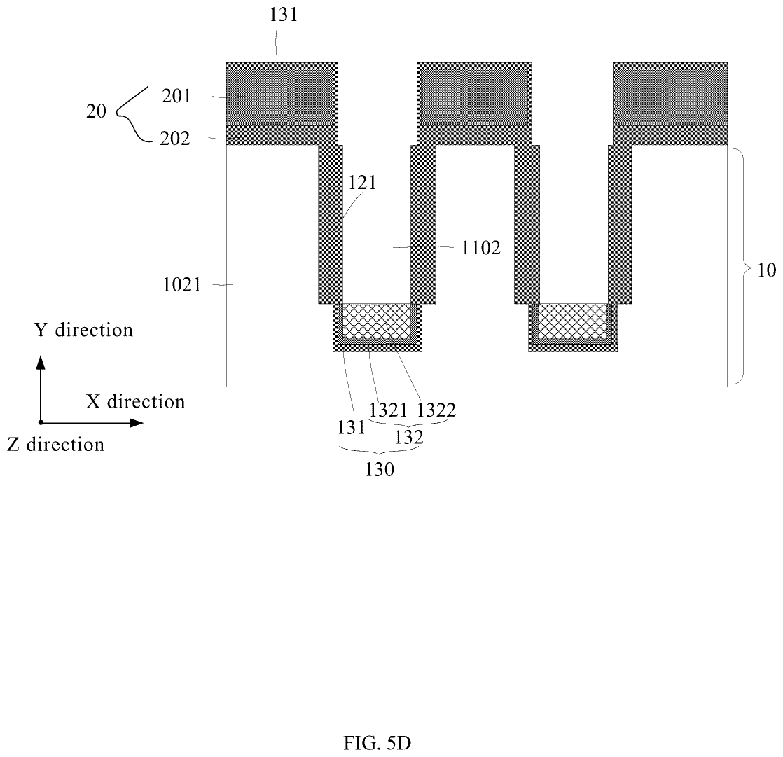

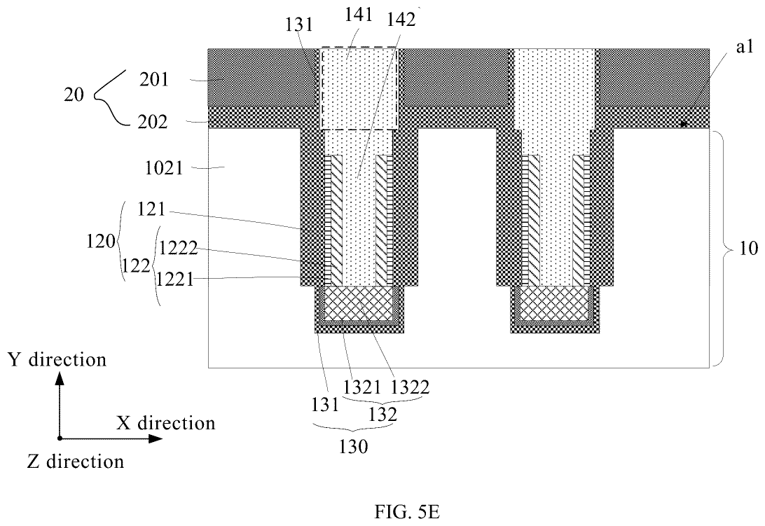

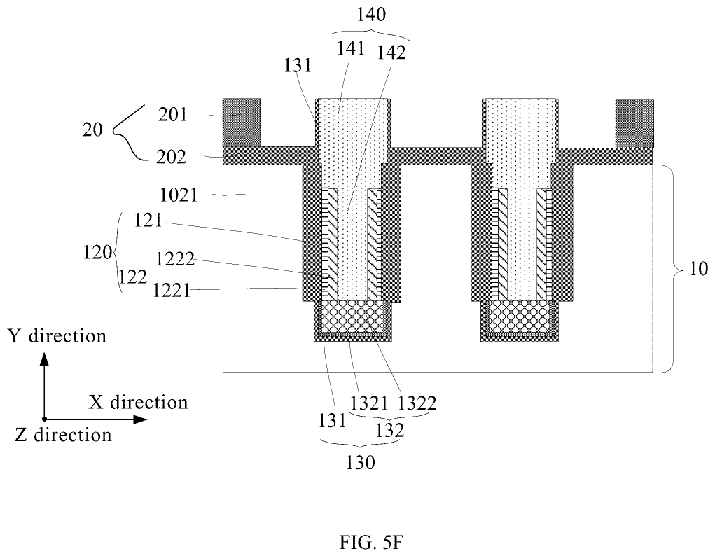

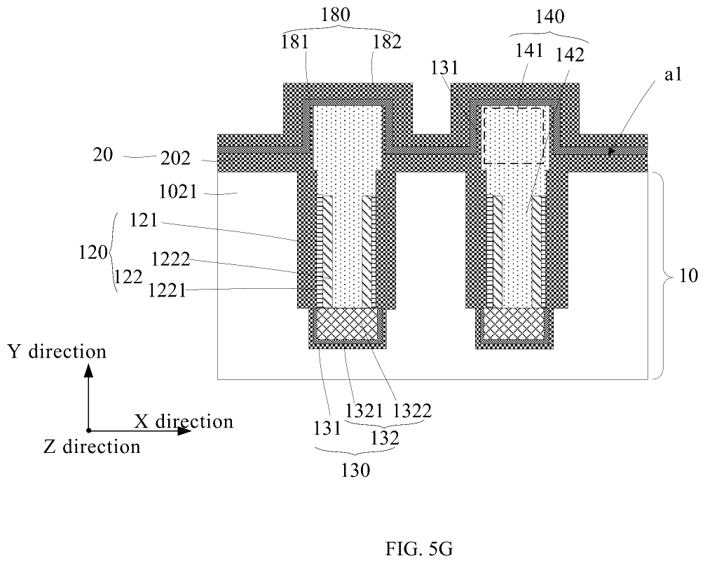

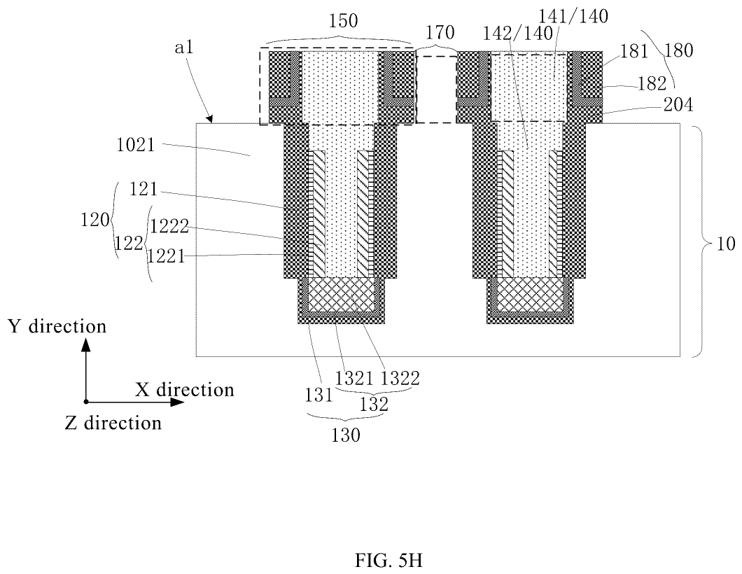

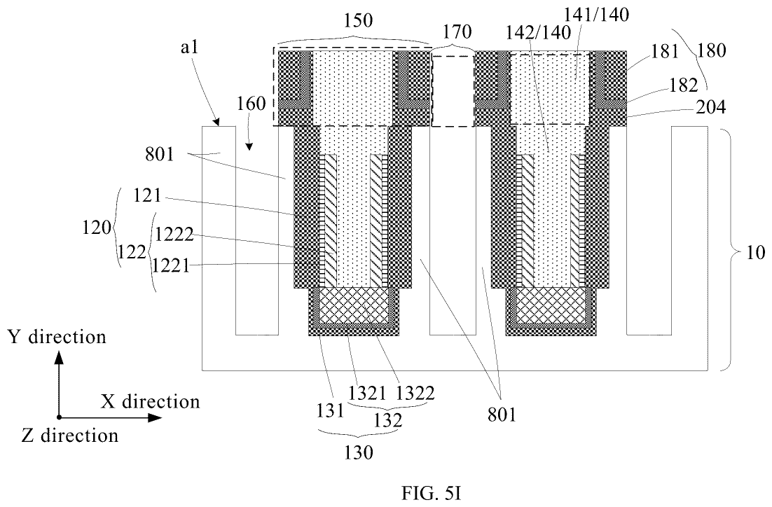

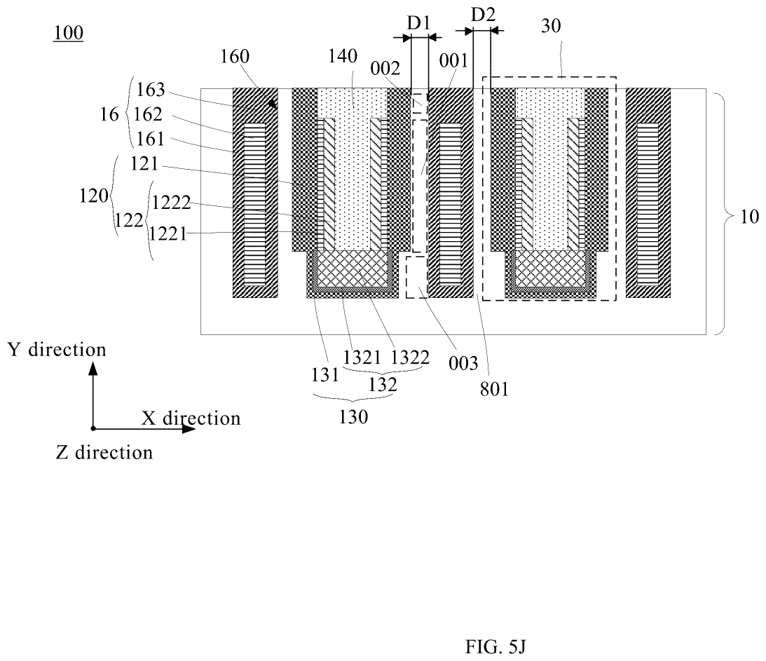

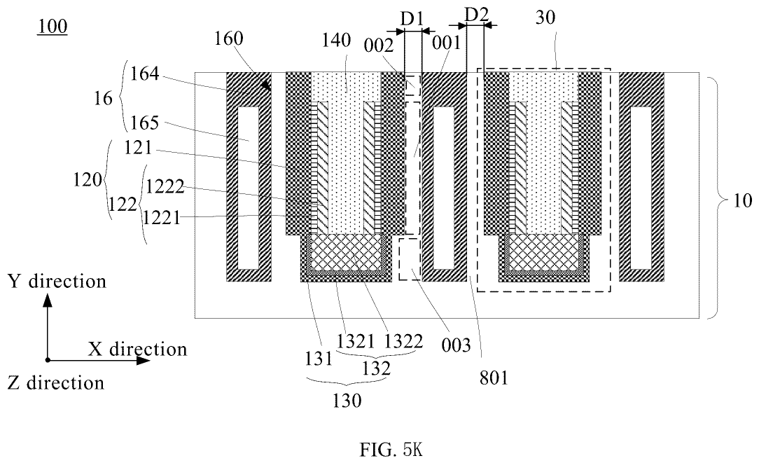

FIG. 4A is a flow diagram of a fabrication method of the semiconductor structure 100 provided by some examples of the present disclosure. FIG. 4B is a flow diagram of another fabrication method of the semiconductor structure 100 provided by some examples of the present disclosure. FIG. 4C is a flow diagram of yet another fabrication method of the semiconductor structure 100 provided by some examples of the present disclosure. FIG. 4D is a flow diagram of still another fabrication method of the semiconductor structure 100 provided by some examples of the present disclosure. FIGS. 5A-5K are structural diagrams corresponding to some steps in the fabrication method of the semiconductor structure 100 provided by some examples of the present disclosure.

Referring to FIG. 4A, the fabrication method of the semiconductor structure 100 comprises S1-S4.

S1. Forming a plurality of first trenches in a semiconductor base, e.g., from a first surface of the semiconductor base, where the first trenches extend along a first direction.

In S1, referring to FIG. 5A, the semiconductor base 10 comprises a plurality of parallel semiconductor walls 102 extending in an X direction, and adjacent ones of the semiconductor walls 102 are separated by a trench isolation wall 104. In some implementations, for example, a lithography process may be performed to pattern a silicon substrate 101 using an etching mask (e.g., at least one of a photoresist mask or a hard mask), and one or more dry etching and/or wet etching processes (e.g., RIE) are performed to etch a trench 103 in the silicon substrate 101. As such, the semiconductor walls 102 extending vertically in the silicon substrate 101 can be formed. Bottoms of the semiconductor walls 102 may be located below a top surface of the silicon substrate 101. Since the semiconductor walls 102 are formed by etching the silicon substrate 101, the semiconductor walls 102 may have the same material as the silicon substrate 101, such as monocrystalline silicon.

The trench isolation wall 104 is formed in the trench 103. In some implementations, one or more thin film deposition processes (including, but not limited to, CVD, PVD, ALD, or any combinations thereof) are used to deposit a dielectric (e.g., silicon oxide) to fully fill the trench 103. In some implementations, a planarization process (e.g., CMP) is performed to remove the excessive dielectric deposited beyond the top surface of the silicon substrate 101. As a result, the parallel semiconductor walls 102 can be separated by the trench isolation wall 104.

Furthermore, referring to FIG. 5B, the plurality of first trenches 110 are formed from the first surface al (e.g., the top surface of the silicon substrate 101) of the semiconductor base 10, and the first trenches 110 extend along the first direction. The semiconductor base is made of a base material. The first direction may be parallel to a Z direction. With reference to a reference coordinate system X-Y-Z in FIGS. 5A and 5B, it can be seen that the first trench 110 alternately passes through the semiconductor walls 102 and the trench isolation wall 104 along the Z direction, while the position taken in FIG. 5B is just located at a semiconductor wall 102, that is, the trench isolation wall 104 is shielded by the semiconductor wall 102 and thus is not shown in FIG. 5B. In addition, the first trench 110 separates the semiconductor wall 102 into a plurality of semiconductor bodies 1021. Here, the semiconductor body may comprise the semiconductor pillar 801 of the vertical transistor 810 shown in FIG. 3. For example, in some examples, one semiconductor body 1021 comprises one semiconductor pillar 801; in other examples, one semiconductor body 1021 may be separated into two semiconductor pillars 801 along the X direction. A specific separation process will be introduced below.

In some examples, the fabrication method may further comprise S00 prior to S1.

Referring to FIG. 4B, S00: disposing a mask layer on the first surface of the semiconductor base, wherein the mask layer comprises a plurality of openings.

In S00, referring to FIG. 5B, the mask layer 20 is disposed on the first surface al of the semiconductor base 10, and the mask layer comprises the plurality of openings. As such, with continued reference to FIG. 4B, subsequent S1 may comprise S001: etching the semiconductor base 10 by means of the plurality of openings of the mask layer 20, so as to form the plurality of first trenches 110.

S2. Forming a plurality of gate structures in the plurality of first trenches.

In S2, referring to FIG. 5E, the gate structure 120 may be formed in the first trench 110. The gate structure 120 may be a vertical structure extending along a Y direction (e.g., parallel to sidewalls of the first trench 110), and the gate structure 120 may also extend along the Z direction, to overlap, in the X direction, channel portions of the plurality of semiconductor bodies 1021 arranged as being spaced apart in the Z direction. The gate structure 120 comprises a gate insulation layer 121 (e.g., comprising one or more gate insulation layers 802 in FIG. 3) and a gate layer 122 (e.g., comprising one or more gate layers 803 in FIG. 3), wherein the gate insulation layer 121 is located between the semiconductor body 1021 and the gate layer 122. In an example, the gate layer 122 may comprise a first conductive layer 1221 and a second conductive layer 1222 that are stacked, wherein the first conductive layer 1221 is closer to the gate insulation layer 121 than the second conductive layer 1222. In some examples, the first conductive layer 1221 may comprise titanium nitride, and the second conductive layer 1222 may comprise a tungsten layer.

In some examples, referring to FIG. 4C, the fabrication method further comprises S01 and S02 between S1 and S2.

S01. Forming a first insulation layer on inner walls of the first trench, where a first sub-trench is formed as being surrounded within the first insulation layer.

In S01. referring to FIG. 5C, the first insulation layer 131 is formed on the inner walls of the first trench 110, wherein the first sub-trench 1101 is formed as being surrounded within the first insulation layer 131. The first insulation layer 131 may be formed by depositing oxide through a thin film deposition process (including, but not limited to, CVD, PVD, or ALD, etc.). Here, it may be understood that in the above examples where the mask layer 20 is disposed, the first insulation layer 131 may also cover the mask layer 20 at the same time.

S02. Forming a stop block at the bottom of the first sub-trench to obtain a second sub-trench.

In S02, with continued reference to FIG. 5C, the stop block 132 may be formed at the bottom of the first sub-trench 1101 to obtain the second sub-trench 1102. A dielectric (e.g., silicon nitride or silicon oxide) may be deposited using one or more thin film deposition processes (including, but not limited to, CVD, PVD, ALD, or any combinations thereof) to fill the bottom of the first sub-trench 1101. In an example, the stop block 132 may comprise a stop portion 1322 and a barrier layer 1321 that is located between the stop portion 1322 and the first insulation layer 131. A material of the barrier layer 1321 may include silicon nitride, and a material of the stop portion 1322 may include oxide, such as silicon oxide. During formation of the stop block 132, for example, a layer of a silicon nitride material may be formed first, followed by filling with a silicon oxide material, and finally, part of the silicon nitride material and the silicon oxide material is etched off to obtain the stop block 132.

In some examples, referring to FIG. 4C, the fabrication method further comprises S03 between S1 and S2.

S03. Performing oxidation treatment on sidewalls of the second sub-trench to form the gate insulation layer.

In S03, referring to FIG. 5D, the gate insulation layer 121 may be formed after the oxidation treatment is performed on the sidewalls of the second sub-trench 1102. As can be seen, a thickness of the gate insulation layer 121 is greater than a thickness of the first insulation layer 131, therefore the gate layer 122 can be better separated from the semiconductor body 1021.

S3. Forming a plurality of second trenches in the semiconductor base, .g., from the first surface of the semiconductor base, wherein each second trench is located between two adjacent ones of the first trenches, and the second trenches extend along the first direction. The first direction may be parallel to the Z direction.

In S3, referring to FIG. 5I, the plurality of second trenches 160 may be further formed from the first surface al of the semiconductor base 10. The second trench 160 can divide one semiconductor body 1021 into two opposite semiconductor pillars 801 along the X direction. Such an arrangement is favorable to increase transistor arrangement density and thus is favorable to increase storage density of the semiconductor structure 100.

S4. Forming a plurality of isolation structures in the plurality of second trenches.

In S4, referring to FIGS. 5J and 5K, the isolation structure 16 may be formed in the second trench 160. As such, the two semiconductor pillars 801 are well separated. In some examples, referring to FIG. 5J, a second insulation layer 161 may be formed on inner walls of the second trench 160, with an accommodation trench formed as being surrounded in the second insulation layer 161; an isolation pillar 162 is formed in the accommodation trench; and the accommodation trench is filled with an insulation material 163 to cover the isolation pillar 162. A material of the isolation pillar 162 may include a metal, such as W, Co, Cu, Al, etc., or the material of the isolation pillar 162 may also include TiN, TaN, etc. As such, the isolation structure 16 may have a better support effect. In other examples, referring to FIG. 5K, the second trench 160 is filled with an insulation material 164 to form the isolation structure 16 comprising an air gap 165. Air in the air gap 165 has a relatively large dielectric constant (e.g., about 4 times of the dielectric constant of silicon oxide), such that an insulation effect between the two semiconductor pillars 801 can be improved.

To sum up, some examples of the present disclosure provide a fabrication method of the semiconductor structure 100. Due to the formation of the second trench 160 and the formation of the isolation structure 16 in the second trench 160, more semiconductor pillars 801 may be formed, thereby increasing the transistor density in the semiconductor structure 100. Furthermore, since the semiconductor structure 100 is a memory or a portion in the memory, it is favorable to increase the storage density of the memory.

It is to be noted that, in some implementations, the first trench 110 and the second trench 160 may be formed in a litho-etch-litho-etch (LELE) approach, that is, a layer of lithographic patterns is split onto two or more masks to achieve superposition of image density. However, when lithographic patterns of the first trench 110 and the second trench 160 are split onto different masks using an LELE process, it is not easy to control the overlay (OVL) accuracy during a plurality of lithography processes, which may, for example, result in a large difference in thicknesses of the semiconductor pillars 801 on two sides of the second trench 160 along the X direction, and thus there are problems of process difficulty and high cost. In some other implementations, the first trench 110 and the second trench 160 may be also formed in a spacer double patterning (SADP) approach, that is, an axial pattern is formed through a single lithography and etching process, then a sidewall pattern is formed on sidewalls through an atomic layer deposition and etching process, and the axial pattern (i.e., a sacrificial layer) is removed to form a sidewall hard mask pattern. However, the problems of high cost and process difficulty are also present when the first trench 110 and the second trench 160 are formed in such an approach. Moreover, both of the above implementations form the first trench 110 and the second trench 160 simultaneously, which may easily cause the problem that the semiconductor structure 100 is prone to bend. However, in the above examples of the present disclosure, the first trench 110 may be formed first, with the gate structure 120 being formed in the first trench 110; and then the second trench 160 is formed, with the isolation structure 16 being formed in the second trench 160. As such, the first trench 110 and the second trench 160 are formed in two steps, which can reduce the process difficulty and cost on the one hand, and make the semiconductor structure 100 less prone to bend on the other hand.

The introduction of the fabrication method of the semiconductor structure 100 provided by some examples of the present disclosure continues below. The method improves the process window and increases the overlay margin, for example, improves the problem of large overlay (OVL) deviation caused by the above LELE approach, and at the same time, it is favorable to reduce the process difficulty and cost and make the semiconductor structure 100 less prone to bend.

In some examples, as shown in FIG. 4D, the fabrication method further comprises S04-S07 after S2 and before S3.

S04. Forming a plurality of insulation filling structures, wherein each of the insulation filling structures is located within one of the first trenches and one of the openings that are connected together, and a portion of the insulation filling structure located within the opening is defined as a first portion.

In S04, referring to FIG. 5E in conjunction with FIG. 5B, the insulation filling structure 140 can fully fill the first trench 110 and the opening of the mask layer 20. At this point, the insulation filling structure 140 may be divided into a first portion 141 and a second portion 142, wherein the first portion 141 is located in the opening of the mask layer 20 and the second portion 142 is located in the first trench 110. In some examples, a material of the insulation filling structure 140 may include an insulation material, which may be, for example, a carbon-containing organic substance. Here, the problem that the semiconductor structure 100 is prone to bend may be improved by filling the first trench 110 with the insulation material before forming the second trench.

With continued reference to FIG. 5E, the insulation material may be deposited to form the insulation filling structure 140, and the insulation material can also cover the first insulation layer 131 located above the mask layer 20 in FIG. 5D. Afterwards, the first insulation layer 131 located above the mask layer 20 and the insulation material used to form the insulation filling structure 140 may be removed to form a structure as shown in FIG. 5E.

In some other examples, after the deposition of the insulation material, at least part of the insulation material in the opening of the mask layer 20 may be removed first, for example, removed along a −Y direction to be flush with the first surface al of the semiconductor base 10 or to any height position above the first surface al (the upward direction in the figure, i.e., in the Y direction). Afterwards, other material (which may include other insulation materials or a metal material, in some examples, a material with higher hardness than the original insulation material may be selected) is filled and ground until a first sublayer 201 is exposed. For example, on the basis of the structure as shown in FIG. 5E, the first portion 141 of the insulation filling structure 140 may be replaced with other materials, or part (one-tenth, one-fifth, or one-half, etc.) of the first portion 141 of the insulation filling structure 140 along the −Y direction may be replaced with other materials. In some examples, the hardness of the first portion 141 of the insulation filling structure 140 is greater than the hardness of the second portion 142 of the insulation filling structure 140. In some examples, the first portion 141 of the insulation filling structure 140 may include a metal material.

S05. At least removing a first sublayer located between two adjacent ones of the insulation filling structures, wherein the first sublayer is at least a part of the mask layer.

In S05, referring to FIG. 5E, a part of the first sublayer 201 may be removed, and the first sublayer 201 is at least a part of the mask layer 20. FIG. 5F uses the mask layer 20 further comprising a second sublayer 202 as an example for illustration. It can be understood that, in this example, the second sublayer 202 may be absent, and the second sublayer 202 is not introduced here now. Here, a material of the first sublayer 201 may include oxide (such as silicon oxide) or silicon nitride. FIG. 5F uses the material of the first sublayer 201 being different from a material of the first insulation layer as an example for illustration. For example, the material of the first sublayer 201 may include silicon nitride, and the material of the first insulation layer 131 may include oxide. As such, the first insulation layer 131 may be remained on a side face of the first portion 141 of the insulation filling structure 140 when the first sublayer 201 is removed.

S06. Forming an isolation layer that covers the plurality of insulation filling structures and the first surface.

In S06, referring to FIG. 5G, the isolation layer 180 may cover the plurality of insulation filling structures 140 and the first surface al. In the example of FIG. 5G, the second sublayer 202 may be temporarily omitted, so that the isolation layer 180 can directly cover the first surface al. When the second sub layer 202 is disposed, the isolation layer 180 here can cover the second sublayer 202 to indirectly cover the first surface al as shown in FIG. 5G. Furthermore, the isolation layer 180 covering the insulation filling structure 140 may cover the first portion 141 of the insulation filling structure 140, and when a side face of the first portion 141 has the first insulation layer 131, the isolation layer 180 may also cover the first insulation layer 131 to indirectly cover the side face of the first portion 141.

S07. Etching the semiconductor structure along a target direction using a first etching process, so as to form a plurality of barrier portions and a plurality of third trenches. Referring to FIG. 5G, the target direction points from a side of the semiconductor base 10 facing the isolation layer 180 to a side of the semiconductor base 10 facing away from the isolation layer 180 (i.e., the −Y direction in the figure). In a solution where the mask layer 20 only comprises the first sublayer 201, etching the semiconductor structure 100 may comprise: only etching the isolation layer 180, so as to expose a part of the first surface al and a surface of the first portion of the insulation filling structure 140, thereby forming the barrier portions and the third trenches. When the mask layer 20 further comprises the second sublayer 202, for example, etching may be also performed further downward through the first etching process, so as to remove a part of the first portion 141 and a part of the second sublayer 202 to expose the first surface al, thereby forming the barrier portion 150 and the third trench 170 as shown in FIG. 5H. Referring to FIG. 5H, the barrier portion 150 comprises at least part of the first portion 141 and the isolation layer 180 around the first portion 141 that is not etched off by the first etching process. The third trench 170 is located between two adjacent ones of the barrier portions 150, and the third trench 170 exposes the first surface al. Here, the first etching process may include a dry etching process.

In some examples, referring to FIG. 4D, S3: forming the plurality of second trenches on the first surface of the semiconductor base comprises: S08: etching the semiconductor base along the target direction by means of the plurality of third trenches using a second etching process, so as to form the plurality of second trenches.

In S08, referring to FIG. 5I, the semiconductor base 10 may be etched along the target direction (the −Y direction) using the second etching process (such as a dry etching process) by means of the third trenches 170, so as to form the second trenches 160. Here, the second trench 160 is formed by a self-aligned approach using the previously formed barrier portion 150 as a mask, without separate provision of a new mask layer. The second trench 160 is of high position accuracy, e.g., close to a middle position, and can separate one semiconductor body 1021 into two mirror-symmetrical semiconductor pillars 801. That is, some of the above examples may employ an LE+Self-aligned process approach to improve the process window and increase the overlay margin, for example, to improve the problem of large overlay (OVL) deviation caused by the above LELE approach, reduce the process difficulty and cost at the same time, and make the fabricated semiconductor structure 100 less prone to bend.

In some examples, with continued reference to FIGS. 5G-5I, the isolation layer 180 may comprise a first dielectric layer 181 and a second dielectric layer 182. A material of the first dielectric layer 181 is different from a material of the second dielectric layer 182. As such, the position and width (i.e., dimension of the third trench 170 along the X direction) of the third trench 170 may be better controlled through the first dielectric layer 181 and the second dielectric layer 182. For example, the third trench 170 with a suitable width may be formed at the middle position between the adjacent ones of the barrier portions 150, thus facilitating the subsequent formation of the second trench 160 with a suitable position and width by etching by means of the third trench 170. Of course, in some other examples, the number of the isolation layers 180 may also be set as one, three, or more layers. At this point, the requirements of different design dimensions of the third trench 170 and the second trench 160 can still be met by controlling the number of the isolation layers 180 and the thickness of each layer.

In an example, the material of the first dielectric layer 181 may include silicon nitride, and the material of the second dielectric layer 182 may include oxide (such as silicon oxide). Here, the material of the second dielectric layer 182 may be the same as the material of the above-mentioned first insulation layer 131. As such, the position and width of the third trench 170 may be better controlled, which facilitates the subsequent formation of suitable second trench 160 by etching by means of the third trench 170.

In some examples, referring to FIGS. 5B-5F. S00: disposing the mask layer 20 on the first surface al of the semiconductor base 10 comprises: forming the second sublayer 202 and the first sublayer 201 sequentially on the first surface al of the semiconductor base 10, wherein materials of the first sublayer 201 and the second sublayer 202 are different. As such, the second sublayer 202 may be used as a stop layer during the previous removal of the first sublayer 201. Moreover, the remaining second sublayer 202 may also serve as a part of the barrier portion 150 during the formation of the barrier portion 150, so as to raise a height of the barrier portion 150 (a dimension along the Y direction).

In an example, the material of the first sublayer 201 includes silicon nitride, and the material of the second sublayer 202 includes oxide (such as silicon oxide). As such, due to a large etching selectivity ratio of silicon nitride and the oxide, the second sublayer 202 has a desirable effect of blocking etching, which facilitates the removal of the first sublayer 201.

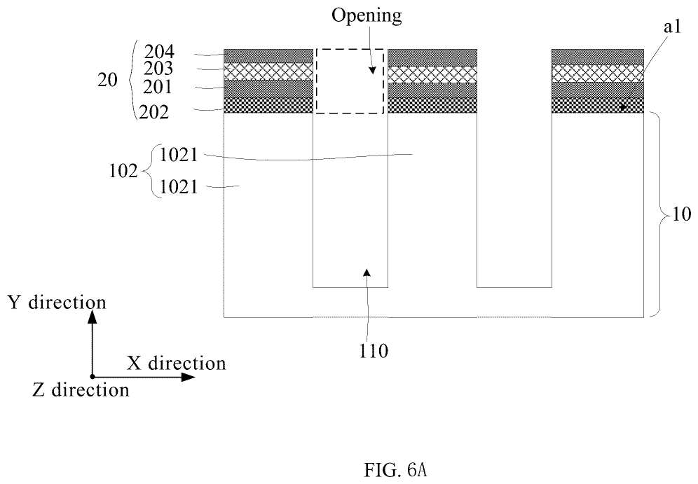

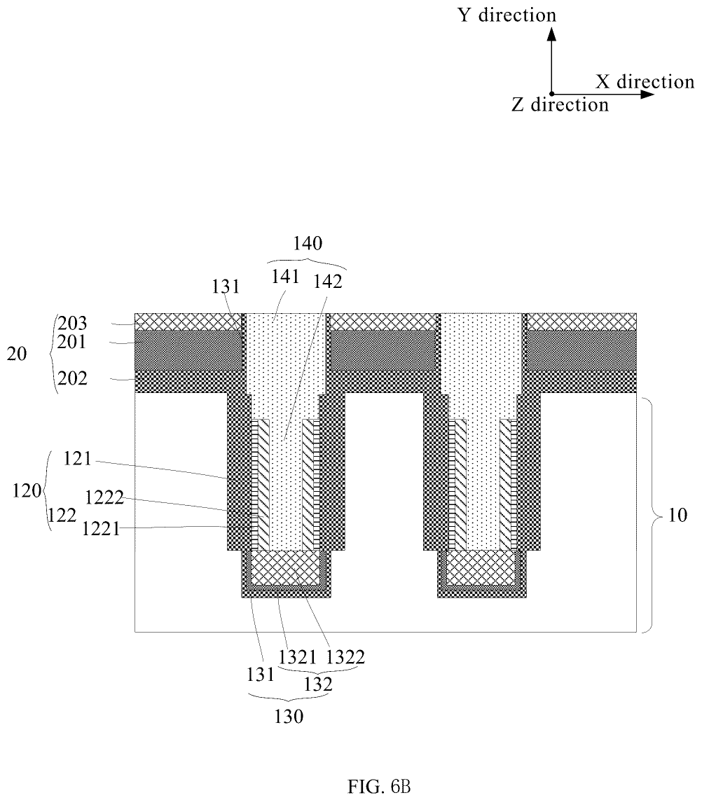

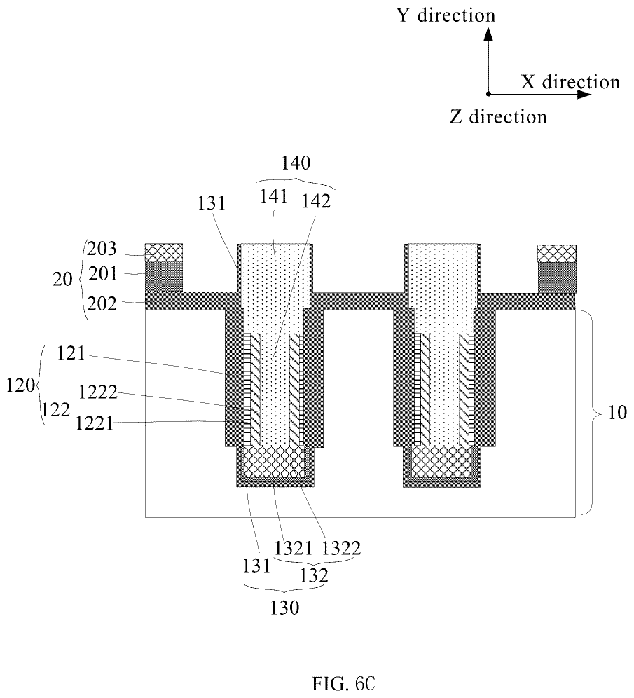

In some examples, as shown in FIG. 6A, S00: disposing the mask layer on the first surface of the semiconductor base further comprises: forming a third sublayer 203 and a fourth sublayer 204 sequentially on the first sublayer 201, wherein the material of the first sublayer 201 is the same as a material of the fourth sublayer 204, the material of the first sublayer 201 is different from a material of the third sublayer 203, and the third sublayer 203 serves as a stop layer during removal of the fourth sublayer 204. Referring to FIG. 6B, the formation of the insulation filling structure 140 requires filling the second trench with the insulation material and then removing the excessive insulation material and the first insulation layer above the mask layer 20 (the direction as shown in the figure). When only the first sublayer 201 is provided, after the excessive insulation material and the first insulation layer are removed, a top surface (i.e., a surface of the mask layer 20 facing away from the semiconductor base 10, which is a top surface of the first sublayer 201 at this point) of the mask layer 20 is likely to be uneven. In this example, by providing the third sublayer 203 and the fourth sublayer 204, the third sublayer 203 may serve as the stop layer so that the excessive insulation material and the first insulation layer can be removed along with the fourth sublayer 204 (for example, removed by a CMP process). Then, the removal process stops at the third sublayer 203, such that the top surface (which is a top surface of the third sublayer 203 at this point) of the mask layer 20 can be more even, and the process difficulty is reduced. In an example, the material of the third sublayer 203 includes polysilicon or titanium nitride, and the material of the fourth sublayer 204 includes silicon nitride. As such, when the excessive insulation material and the first insulation layer are removed along with the fourth sublayer 204, the removal process can desirably stop at the third sublayer 203.

Thereafter, referring to FIG. 6C, the third sublayer 203 above the first sublayer 201 can be removed simultaneously when the first sublayer 201 between two adjacent ones of the insulation filling structures 140 is removed. Subsequent operations are substantially the same as those in the above examples and are not repeated any longer here.

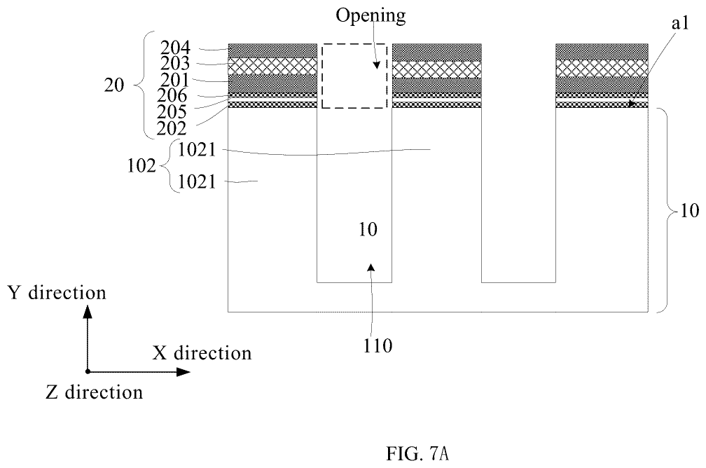

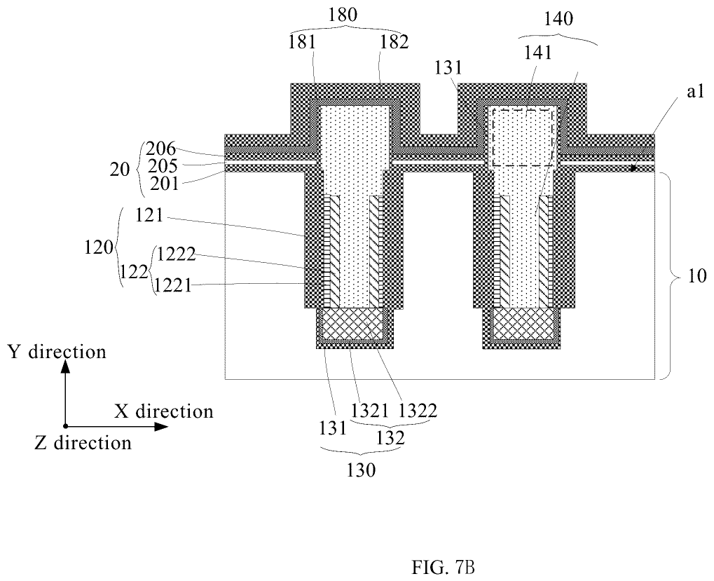

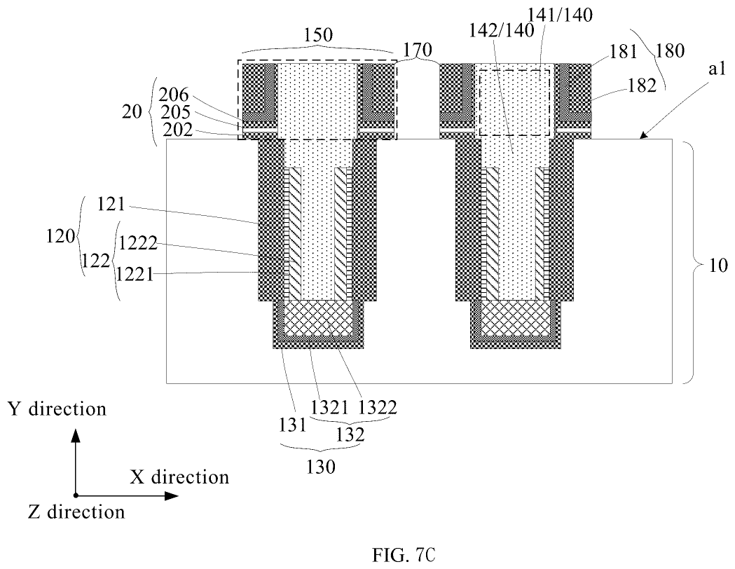

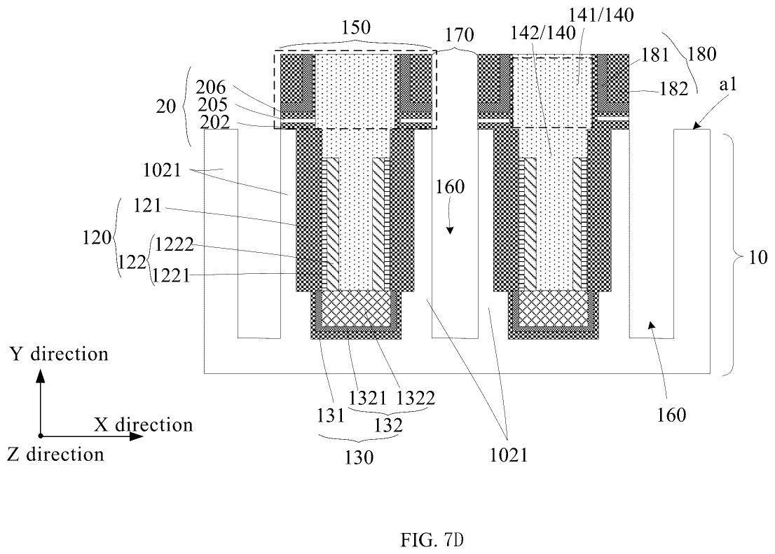

In other examples, as shown in FIG. 7A. S00: disposing the mask layer on the first surface of the semiconductor base further comprises: forming a fifth sublayer 206 and a sixth sublayer 206 sequentially on the second sublayer 202, wherein the fifth sublayer 205 and the sixth sublayer 206 are located between the second sublayer 202 and the first sublayer 201, the material of the second sublayer 202 is the same as a material of the sixth sublayer 206, the material of the second sublayer 202 is different from a material of the fifth sublayer 205, and the fifth sublayer 205 serves as a stop layer during removal of the sixth sublayer 206. FIG. 7A also illustrates the first sublayer 201, the third sublayer 203, and the fourth sublayer 204, which are not be repeated here. For the second sublayer 202, the fifth sublayer 205, and the sixth sublayer 206, reference may be made directly to FIGS. 7B-7D. In FIG. 7B, the isolation layer 180 can cover a surface of the sixth sublayer 206 facing away from the semiconductor base 10. Then, as shown in FIG. 7C, the second sublayer 202, the fifth sublayer 205, and the sixth sublayer 206 may be also opened while etching the first isolation layer 180, so as to expose the first surface al. Thereafter, as shown in FIG. 7D, the second trench 160 may be formed by etching the third trench 170. With reference to FIGS. 5J and 5K, an excessive part above the first surface needs to be removed after the isolation structure 16 is formed. At this point, a CMP process can be used so that a coarse grinding process stops at the fifth sublayer 205. Compared with the case where the fifth sublayer 205 and the sixth sublayer 206 are not disposed, this example can better control the grinding process and reduce the process difficulty. Thereafter, a structure as shown in FIG. 5J or 5K can be formed just by fine grinding of the remaining second sublayer 202 and the fifth sublayer 205. In an example, the material of the fifth sublayer 205 includes silicon nitride, and the material of the sixth sublayer 206 includes oxide. As such, due to a significant difference between silicon nitride and silicon oxide, the grinding process can desirably stop at the fifth sublayer 205 after the sixth sublayer 206 is removed.

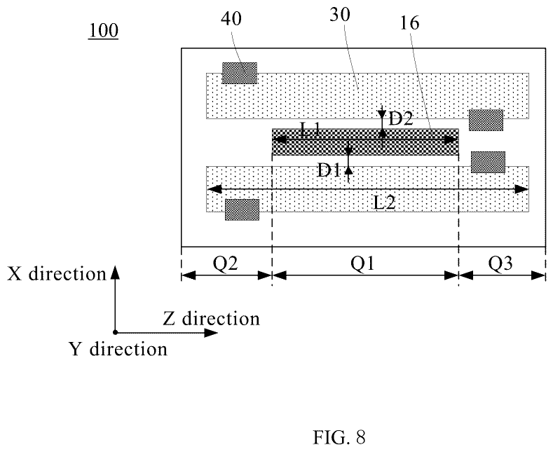

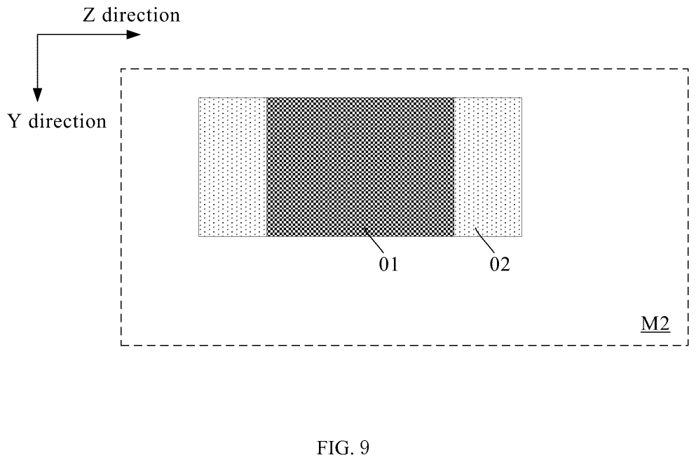

The semiconductor structure 100 provided by some examples of the present disclosure is further introduced below in conjunction with FIGS. 5J, 5K, 8, and 9. FIG. 8 is a top view of the semiconductor structure in some examples of the present disclosure. FIG. 9 is a projection view of an isolation structure and a gate filling structure in some examples of the present disclosure.

As shown in FIGS. 5J, 5K, 8, and 9, the semiconductor structure 100 provided by some examples of the present disclosure comprises a plurality of gate filling structures 30, a plurality of isolation structures 16, and a plurality of semiconductor pillars 801. The plurality of gate filling structures 30 extend along the first direction (i.e., the Z direction). Each isolation structure 16 is located between two adjacent ones of the gate filling structures 30. The isolation structure 16 extends along the first direction (i.e., the Z direction), and an arrangement direction of the isolation structures 16 and the gate filling structures 30 is a second direction (i.e., the X direction). Each semiconductor pillar 801 is located between the isolation structure 16 and the gate filling structure 30. The semiconductor pillar 801 extends along a third direction (i.e., the Y direction) that intersects a first reference plane, and the first direction and the second direction are in the first reference plane. A length L1 of the isolation structure 16 along the first direction is less than a length L2 of the gate filling structure 30 along the first direction.

For the semiconductor structure 100 in this example, the plurality of semiconductor pillars 801 may be disposed between the isolation structure 16 and the gate filling structures 30 on two sides of the isolation structure 16, thereby forming a plurality of vertical transistors, which is favorable to increase the storage density of the semiconductor structure 100. Moreover, the length L1 of the isolation structure 16 along the first direction is less than the length L2 of the gate filling structure 30 along the first direction, such that the length of the isolation structure 16 is short. For example, the isolation structure 16 may not extend to an edge area Q2 (such as an ineffective storage area). Therefore, the isolation structure 16 may be disposed only in a core area Q1 that requires electrical isolation, without the need to dispose the isolation structure 16 in the edge area Q2 that does not require electrical isolation, which is also favorable to reduce the cost during the fabrication of the semiconductor structure 100.

In some examples, as shown in FIG. 8, the semiconductor structure 100 has the core area Q1 and the edge area Q2; the gate filling structure 30 is located in the core area Q1 and the edge area Q2; and the isolation structure 16 is located in the core area Q1. As such, it is favorable to shorten the isolation structure 16 and reduce the fabrication cost.

In some examples, as shown in FIG. 9, the first direction (i.e., the Z direction) and the third direction (i.e., the Y direction) are in a second reference plane M2; an orthographic projection of the isolation structure 16 on the second reference plane M2 is a first orthographic projection 01, and an orthographic projection of the gate filling structure 30 on the second reference plane M2 is a second orthographic projection 02; and two ends of the first orthographic projection 01 are located between two ends of the second orthographic projection 02 along the first direction. As such, the isolation structure 16 does not extend or extends as little as possible to the edge area Q2, which is favorable to shorten the isolation structure 16 and reduce the fabrication cost.

In some examples, referring to FIGS. 5J, 5K, and 8, distances (D1, D2) between the isolation structure 16 and two adjacent gate filling structures 30 along the second direction (i.e., the X direction) are equal. As such, thicknesses of the semiconductor pillars 801 located on two sides of the isolation structure 16 may be equal, which is favorable to ensure yield of the vertical transistors on the two sides of the isolation structure 16. Moreover, the position of the isolation structure 16 is close to the middle, which can also achieve a desirable isolation effect.

In some examples, a difference in distances between the isolation structure 16 and the two adjacent gate filling structures 30 along the second direction (i.e., the X direction) is less than or equal to 10 nm. In an example, the difference in the distances between the isolation structure 16 and the two adjacent gate filling structures 30 along the second direction may be also less than or equal to 5 nm. In an example, the distance difference between the isolation structure 16 and two adjacent ones of the gate filling structures 30 along the second direction may be 10 nm, 8 nm, 6 nm, 5 nm, 4 nm, 2 nm, 1 nm, etc. In this example, the distance difference between the isolation structure 16 and two adjacent ones of the gate filling structures 30 is small, which is favorable to ensure the yield of the vertical transistors on the two sides of the isolation structure 16. Moreover, the position of the isolation structure 16 is close to the middle, which can also achieve a desirable isolation effect.

It is to be noted that, the distance (D1, D2) between the isolation structure 16 and the gate filling structure 30 may refer to a distance between adjacent boundaries of the isolation structure 16 and the gate filling structure 30 (as shown in FIGS. 5J, 5K, and 8), or may be a distance between a center of the isolation structure 16 and a center of the gate filling structure 30, or may also refer to a distance from an edge of the isolation structure 16 near an edge of the gate filling structure 30 to any reference in the gate filling structure 30. In some examples, as shown in FIGS. 5J and 5K, the gate filling structure 30 comprises a stop structure 130 and the gate structure 120 that are stacked along the third direction (Y direction), wherein the stop structure 130 comprises the stop block 132 and the first insulation layer 131 that is located between the stop block 132 and the semiconductor pillar 801, and the gate structure 120 comprises the gate layer 122 and the gate insulation layer 121 that is located between the gate layer 122 and the semiconductor pillar 801. The above reference may be the gate insulation layer 121 here, or may be the gate layer 122 here, or may be the first insulation layer 131 or the stop block 132 here. In some examples, distances between the isolation structure 16 and the gate insulation layers 121 in the two adjacent gate filling structures 30 are equal along the second direction (X direction), as shown in FIGS. 5J, 5K, and 8.

In some examples, as shown in FIG. 8, the semiconductor structure further comprises a plurality of gate cut-off structures 40. It can be understood that when the plurality of gate structures 120 are formed in the first trenches, the gate layers 122 in the gate structures 120 are in ring shapes, such that the gate layers (or referred as word lines) of two rows of vertical transistors are connected together. The gate cut-off structure 40 may cut off the two word lines, thereby facilitating independent control of the two rows of vertical transistors.

In some examples, as shown in FIGS. 5J and 5K, the semiconductor pillar 801 comprises a channel portion 001, a first electrode 002, and a second electrode 003, wherein the channel portion 001 is located between the first electrode 002 and the second electrode 003 along the third direction (Y direction), and the channel portion 001 overlap the gate layer 122 along the second direction (X direction). A storage unit (the storage unit 820 as shown in FIG. 3) may be electrically connected with the first electrode 002. As such, the memory cell 80 as shown in FIG. 3 can be formed.

In an example, after structures of FIGS. 5J and 5K are formed, the fabrication of the storage unit 820, such as a capacitor, may continue above the first electrode 002 of the semiconductor pillar 801. Thereafter, the semiconductor structure 100 may be turned over, and the semiconductor base is ground until the stop structure 130, so as to expose the second electrodes 003 of the plurality of semiconductor pillars 801. Thereafter, a plurality of bit lines may be fabricated to connect the second electrodes 003 of the plurality of semiconductor pillars 801.

As noted above, the semiconductor structure provided by the examples of the present application can be a memory or a part of the memory. A memory formed based on the semiconductor structure provided by the examples of the present application is introduced below.

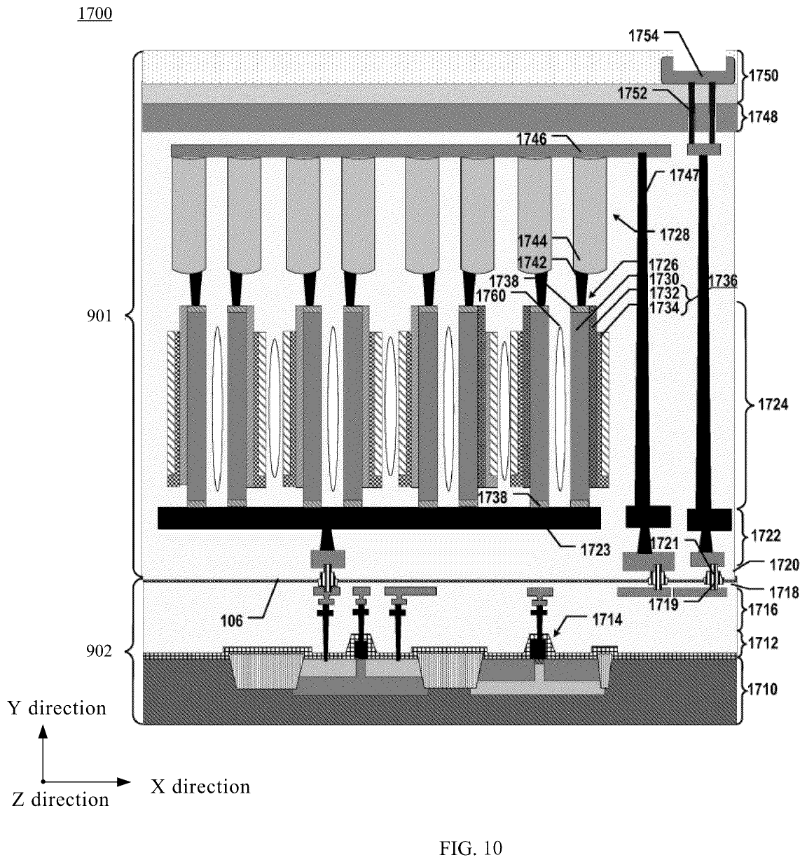

FIG. 10 is a structural diagram of a memory in some examples of the present disclosure.

As shown in FIG. 10, the memory comprises a first semiconductor structure 901 (for example, may be the semiconductor structure provided in the examples of the present disclosure) and a second semiconductor structure 902. According to some implementations, the first semiconductor structure 901 and the second semiconductor structure 902 are bonded at a bonding interface therebetween. As shown in FIG. 10, the second semiconductor structure 902 may comprise a substrate 1710 that may include silicon (e.g., monocrystalline silicon, or c-Si), SiGe, GaAs, Ge, SOI, or any other suitable materials.

The second semiconductor structure 902 may further comprise a peripheral circuit 1712 on the substrate 1710. In some implementations, the peripheral circuit 1712 comprises a plurality of transistors 1714 (e.g., at least one of a planar transistor or a 3D transistor). A trench isolation (e.g., a shallow trench isolation (STI)) and a doped area (e.g., a well, a source, and a drain of a transistor 1714) may be also formed on or in the substrate 1710.

In some implementations, the second semiconductor structure 902 further comprises an interconnection layer 1716 above the peripheral circuit 1712 to transmit electrical signals to and from the peripheral circuit 1712. The interconnection layer 1716 may comprise a plurality of interconnections (also referred to as “contacts” herein), comprising lateral interconnection lines and VIA contacts. The interconnection layer 1716 may further comprise one or more ILD layers, in which interconnection lines and via contacts may be formed. That is, the interconnection layer 1716 may comprise the interconnection lines and the via contacts in the plurality of ILD layers. In some implementations, the peripheral circuits 1712 are coupled to each other through the interconnections in the interconnection layers 1716. The interconnection in the interconnection layer 1716 may include a conductive material, including, but not limited to, W, Co, Cu, Al, doped silicon, silicides, or any combination thereof. The ILD layer may be formed from a dielectric material, including, but not limited to, silicon oxide, silicon nitride, silicon oxynitride, a low k dielectric, or any combination thereof.

As shown in FIG. 10, the second semiconductor structure 902 may further comprise a bonding layer 1718 at the bonding interface 106 and above the interconnection layer 1716 and the peripheral circuit 1712. The bonding layer 1718 may comprise a plurality of bonding contacts 1719 and a dielectric that electrically isolates the bonding contacts 1719. The bonding contacts 1719 may include a conductive material, such as Cu. A remaining region of the bonding layer 1718 may be formed from a dielectric material (e.g., silicon oxide). The bonding contacts 1719 in the bonding layer 1718 and the surrounding dielectric may be used for hybrid bonding. Similarly, as shown in FIG. 10, the first semiconductor structure 901 may further comprise a bonding layer 1720 at the bonding interface 106 and above the bonding layer 1718 of the second semiconductor structure 902. The bonding layer 1720 may comprise a plurality of bonding contacts 1721 and a dielectric that electrically isolates the bonding contacts 1721. The bonding contacts 1721 may include a conductive material, such as Cu. A remaining region of the bonding layer 1720 may be formed from a dielectric material (e.g., silicon oxide). The bonding contacts 1721 in the bonding layer 1720 and the surrounding dielectric may be used for hybrid bonding. According to some implementations, the bonding contacts 1721 are in contact with the bonding contacts 1719 at the bonding interface 106.

The first semiconductor structure 901 may be bonded face-to-face to the top of the second semiconductor structure 902 at the bonding interface 106. In some implementations, as a result of the hybrid bonding (also referred to as “metal/dielectric hybrid bonding”), the bonding interface 106 is disposed between the bonding layers 1720 and 1718. The hybrid bonding is a direct bonding technique (e.g., forming bonding between surfaces without using an intermediate layer, e.g., a solder or an adhesive) and can obtain metal-metal bonding and dielectric-dielectric bonding simultaneously. In some implementations, the bonding interface 106 is a location where the bonding layers 1720 and 1718 meet and bond to each other. In practice, the bonding interface 106 may be a layer with a particular thickness, which comprises a top surface of the bonding layer 1718 of the second semiconductor structure 902 and a bottom surface of the bonding layer 1720 of the first semiconductor structure 901. In some implementations, the first semiconductor structure 901 further comprises an interconnection layer 1722 that comprises a bit line 1723 above the bonding layer 1720 to transmit electrical signals. The interconnection layer 1722 may comprise a plurality of interconnections, such as an MEOL interconnection and a BEOL interconnection. In some implementations, the interconnections in the interconnection layer 1722 further include a local interconnection. The interconnection layer 1722 may further comprise one or more ILD layers, in which interconnection lines and via contacts may be formed. The interconnection in the interconnection layer 1722 may include a conductive material, including, but not limited to, W, Co, Cu, Al, doped silicon, silicides, or any combination thereof. The ILD layer may be formed from a dielectric material, including, but not limited to, silicon oxide, silicon nitride, silicon oxynitride, a low k dielectric, or any combination thereof. In some implementations, the peripheral circuit 1712 comprises a word line driver/row decoder coupled to word line contacts in the interconnection layer 1722 through the bonding contacts 1721 and 1719 in the bonding layers 1720 and 1718 and the interconnection layer 1716. In some implementations, the peripheral circuit 1712 comprises a bit line driver/column decoder coupled to a bit line 1723 and bit line contacts (if any) in the interconnection layer 1722 through the bonding contacts 1721 and 1719 in the bonding layers 1720 and 1718 and the interconnection layer 1716.

In some implementations, the first semiconductor structure 901 comprises a DRAM device, wherein memory cells are provided in a form of an array of DRAM cells 1724 above the interconnection layer 1722 and the bonding layer 1720. That is, the interconnection layer 1722 comprising the bit line 1723 may be disposed between the bonding layer 1720 and the array of the DRAM cells 1724. It is to be understood that the cross-section of the 3D memory in FIG. 10 can be obtained by taking along a bit line direction, and one bit line 1723 in the interconnection layer 1722 extending laterally can be coupled to a column of DRAM cells 1724. Each DRAM cell 1724 may comprise a vertical transistor 1726 (for example, which may be the above-mentioned vertical transistor 810) and a capacitor 1728 coupled to the vertical transistor 1726 (for example, which may be the above-mentioned storage unit 820). The DRAM cell 1724 may be a 1T1C cell consisting of one transistor and one capacitor. It is to be understood that the DRAM cell 1724 may be of any suitable configuration, such as a 2T1C cell, a 3T1C cell, etc. The vertical transistor 1726 may be a MOSFET used to switch the corresponding DRAM cell 1724. In some implementations, the vertical transistor 1726 comprises a semiconductor pillar 1730 (for example, which may be the above-mentioned semiconductor pillar 801) extending vertically, and a gate structure 1736 (for example, which may be the above-mentioned gate structure 120) that is in contact with a side face of the semiconductor pillar 1730 in the bit line direction (the y direction). In a single-gate vertical transistor, the semiconductor pillar 1730 may have a cubic or cylindrical shape, and the gate structure 1736 may adjoin a single side face of the semiconductor pillar 1730 in a plan view, for example, as shown in FIG. 10. In some implementations, the gate structure 1736 comprises a gate electrode 1734 (for example, which may be the above-mentioned gate layer 122) and a gate dielectric 1732 (for example, which may be the above-mentioned gate insulation layer 121) laterally located between the gate electrode 1734 and the semiconductor pillar 1730 in the bit line direction. In some implementations, the gate dielectric 1732 adjoins a side face of the semiconductor pillar 1730, and the gate electrode 1734 adjoins the gate dielectric 1732.

In some implementations, the semiconductor pillar 1730 may have a larger vertical dimension (e.g., a depth) than the gate electrode 1734 (e.g., in the Y direction), and neither an upper end nor a lower end of the semiconductor pillar 1730 is flush with a corresponding end of the gate electrode 1734. Therefore, a short circuit between the bit line 1723 and the word line/gate electrode 1734 or between the word line/gate electrode 1734 and the capacitor 1728 may be avoided. The vertical transistor 1726 may further comprise a source and a drain (both referred to as 1738 due to their interchangeable positions) respectively disposed at two ends (the upper end and the lower end) of the semiconductor pillar 1730 in the vertical direction (Y direction). In some implementations, one (e.g., at the upper end in FIG. 10) of the source and the drain 1738 is coupled to capacitor 1728, and the other one (e.g., at the lower end in FIG. 10) of the source and the drain 1738 is coupled to the bit line 1723.

In some implementations, the semiconductor pillar 1730 includes a semiconductor material, such as monocrystalline silicon, polysilicon, amorphous silicon, Ge, any other semiconductor materials, or any combination thereof. In one example, the semiconductor pillar 1730 may include monocrystalline silicon. The source and the drain 1738 may be doped with an N-type dopant (e.g., P or As) or a P-type dopant (e.g., B or Ga) at a desired doping level. In some implementations, a silicide layer (e.g., a metal silicide layer) is formed between the source and the drain 1738 and the bit line 1723 or the first electrode 1742 to reduce contact resistance. In some implementations, the gate dielectric 1732 includes a dielectric material such as silicon oxide, silicon nitride, or a high k dielectric, including, but not limited to, Al₂O₃, HfO₂, Ta₂O₅, ZrO₂, TiO₂, or any combination thereof. In some implementations, the gate electrode 1734 includes a conductive material, including, but not limited to, W, Co, Cu, Al, TiN, TaN, polysilicon, silicides, or any combination thereof. In some implementations, the gate electrode 1734 comprises a plurality of conductive layers, such as a W layer over a TiN layer, as shown in FIG. 10. In one example, the gate structure 1736 may be a “gate oxide/gate polysilicon” gate, wherein the gate dielectric 1732 includes silicon oxide, and the gate electrode 1734 includes doped polysilicon. In another example, the gate structure 1736 may be an HKMG, wherein the gate dielectric 1732 comprises a high k dielectric, and the gate electrode 1734 comprises a metal.

As noted above, since the gate electrode 1734 may be a part of the word line or extend as the word line in a word line direction (e.g., the Z direction in FIG. 10) as shown in FIG. 10, the first semiconductor structure 901 of a 3D memory device 1700 may also comprise a plurality of word lines each extending in the word line direction (the Z direction). Each word line can be coupled to a row of DRAM cells 1724. That is, the bit line 1723 and the word line can extend upward in two lateral directions perpendicular to each other, and the semiconductor pillar 1730 of the vertical transistor 1726 can extend in a vertical direction that is perpendicular to the two lateral directions along which the bit line 1723 and the word line extend. According to some implementations, the word line is in contact with word line contacts (not shown). In some implementations, the word line comprises a conductive material, including, but not limited to, W, Co, Cu, Al, TiN, TaN, polysilicon, silicides, or any combination thereof. In some implementations, the word line comprises a plurality of conductive layers, such as a W layer (e.g., the aforementioned second conductive layer 1222) over a TiN layer (e.g., the aforementioned first conductive layer 1221), as shown in FIG. 10. According to some implementations, the vertical transistor 1726 extends vertically through the word line and is in contact with the word line, and the vertical transistor 1726 is in contact with the bit line 1723 (or in contact with a bit line contact, if any) at the source or the drain 1738 at its lower end. Therefore, due to the vertical arrangement of the vertical transistor 1726, the word line and the bit line 1723 can be disposed in different planes in the vertical direction, which simplifies routing of the word line and the bit line 1723.

In some implementations, the bit line 1723 is disposed vertically between the bonding layer 1720 and the word line, and the word line is disposed vertically between the bit line 1723 and the capacitor 1728. The word line may be coupled to the peripheral circuit 1712 in the second semiconductor structure 902 through the word line contacts (not shown) in the interconnection layer 1722, the bonding contacts 1721 and 1719 in the bonding layers 1720 and 1718, and the interconnections in the interconnection layer 1716. Similarly, the bit line 1723 in the interconnection layer 1722 may be coupled to the peripheral circuit 1712 in the second semiconductor structure 902 through the bonding contacts 1721 and 1719 in the bonding layers 1720 and 1718 and the interconnections in the interconnection layer 1716.

As noted above, the vertical transistors 1726 may be arranged in a mirror-symmetrical manner, so as to increase the density of the DRAM cells 1724 in the bit line direction (the X direction). As shown in FIG. 10, according to some implementations, two adjacent ones of the vertical transistors 1726 in the bit line direction are mirror-symmetrical with each other with respect to a trench isolation 1760 (e.g., corresponding to the aforementioned isolation structure 16). That is, the first semiconductor structure 901 may comprise a plurality of trench isolations 1760, wherein each trench isolation 1760 extends parallel to the word line in the word line direction (the x direction) and is disposed between the semiconductor pillars 1730 of two adjacent rows of the vertical transistors 1726. In some implementations, the vertical transistors 1726 separated by the trench isolation 1760 are mirror-symmetrical with each other with respective to the trench isolation 1760. The trench isolation 1760 may be formed from a dielectric material, including, but not limited to, silicon oxide, silicon nitride, silicon oxynitride, a low k dielectric, or any combination thereof. It is to be understood that the trench isolation 1760 may comprise air gaps each laterally disposed between adjacent ones of the semiconductor pillars 1730. As described below with respect to the fabrication process, the air gap may be formed due to a relatively small spacing between the vertical transistors 1726 in the bit line direction (e.g., the y direction). On the other hand, compared with some dielectrics (e.g., silicon oxide), the air in the air gap has a larger dielectric constant (e.g., about 4 times of the dielectric constant of silicon oxide) and thus can improve the isolation effect between the vertical transistors 1726 (and between rows of the DRAM cells 1724). Similarly, in some implementations, depending on a spacing of the word lines/gate electrodes 1734 in the bit line direction, an air gap is also laterally formed between the word lines/gate electrodes 1734 in the bit line direction.

As shown in FIG. 10, in some implementations, the capacitor 1728 comprises the first electrode 1742 above and in contact with the source or the drain 1738 (e.g., the upper end of the semiconductor pillar 1730) of the vertical transistor 1726. The capacitor 1728 may further comprise a capacitor dielectric 1744 above and in contact with the first electrode 1742, and a second electrode 1746 above and in contact with the capacitor dielectric 1744. That is, the capacitor 1728 may be a vertical capacitor, with the electrodes 1742 and 1746 and the capacitor dielectric 1744 being stacked vertically (in the Y direction), and the capacitor dielectric 1744 may be sandwiched between the electrodes 1742 and 1746. In some implementations, each first electrode 1742 is coupled to the source or the drain 1738 of the respective vertical transistor 1726 in the same DRAM cell, while all the second electrodes 1746 are part of a common plate (e.g., a common ground) coupled to the ground. As shown in FIG. 10, the first semiconductor structure 901 may further comprise a capacitor contact 1747 in contact with the common plate of the second electrode 1746, which is used for coupling the second electrode 1746 of the capacitor 1728 to the peripheral circuit 1712 or directly coupling it to the ground. In some implementations, the ILD layer with the capacitor 1728 formed therein comprises the same dielectric material as the two ILD layers into which the semiconductor pillars 1730 extend, such as silicon oxide.

It is to be understood that, the structure and configuration of the capacitor 1728 are not limited to the example in FIG. 10, and may include any suitable structure and configuration, such as a planar capacitor, a stacked capacitor, a multi-fin capacitor, a cylindrical capacitor, a trench capacitor, or a substrate-plate capacitor. In some implementations, the capacitor dielectric 1744 comprises a dielectric material such as silicon oxide, silicon nitride, or a high k dielectric, including, but not limited to, Al₂O₃, HfO₂, Ta₂O₅, ZrO₂, TiO₂, or any combination thereof. It is to be understood that, in some examples, the capacitor 1728 may be a ferroelectric capacitor used in a FRAM cell, and the capacitor dielectric 1744 may be replaced by a ferroelectric layer having a ferroelectric material (e.g., PZT or SBT). In some implementations, the electrodes 1742 and 1746 comprise a conductive material, including, but not limited to, W, Co, Cu, Al, TiN, TaN, polysilicon, silicides, or any combination thereof.

As shown in FIG. 10, according to some implementations, the vertical transistor 1726 extends vertically through the word line and is in contact with the word line. The vertical transistor 1726 is in contact with the bit line 1723 at the source or the drain 1738 at its lower end, and the vertical transistor 1726 is in contact with the electrode 1742 of the capacitor 1728 at the source or the drain 1738 at its upper end. That is, due to the vertical arrangement of the vertical transistor 1726, the bit line 1723 and the capacitor 1728 can be disposed in different planes in the vertical direction, and coupled to opposite ends of the vertical transistor 1726 of the DRAM cell 1724 in the vertical direction. In some implementations, the bit line 1723 and the capacitor 1728 are disposed on opposite side faces of the vertical transistor 1726 in the vertical direction, which simplifies the routing of the bit line 1723 and reduces coupling capacitance between the bit line 1723 and the capacitor 1728, compared with a conventional DRAM cell where a bit line and a capacitor are disposed on the same side face of a planar transistor.

As shown in FIG. 10, in some implementations, the vertical transistor 1726 is disposed vertically between the capacitor 1728 and the bonding interface 106. That is, the vertical transistor 1726 may be arranged closer to the peripheral circuit 1712 of the second semiconductor structure 902 and the bonding interface 106 than the capacitor 1728. Since the bit line 1723 and the capacitor 1728 are coupled to the opposite ends of the vertical transistor 1726, as described above, according to some implementations, the bit line 1723 (serving as a part of the interconnection layer 1722) is disposed vertically between the vertical transistor 1726 and the bonding interface 106. As a result, the interconnection layer 1722 comprising the bit line 1723 may be arranged close to the bonding interface 106 to reduce distance and complexity of interconnection routing.

In some implementations, the first semiconductor structure 901 further comprises a substrate 1748 disposed above the DRAM cell 1724. As described below with respect to the fabrication process, the substrate 1748 may be a part of a carrier wafer. It is to be understood that, in some examples, the substrate 1748 may not be included in the first semiconductor structure 901.

As shown in FIG. 10, the first semiconductor structure 901 may further comprise the substrate 1748 and a pad-out interconnection layer 1750 above the DRAM cell 1724. The pad-out interconnection layer 1750 may comprise interconnections in the one or more ILD layers, e.g., a contact pad 1754. The pad-out interconnection layer 1750 and the interconnection layer 1722 may be formed on opposite side faces of the DRAM cell 1724. According to some implementations, the capacitor 1728 is disposed vertically between the vertical transistor 1726 and the pad-out interconnection layer 1750. In some implementations, for example, for the purpose of pad-out, the interconnection in the pad-out interconnection layer 1750 can transmit electrical signals between the 3D memory device 1700 and an external circuit. In some implementations, the first semiconductor structure 901 further comprises one or more contacts 1752 that extend through a part of the pad-out interconnection layer 1750 and the substrate 1748 to couple the pad-out interconnection layer 1750 to the DRAM cell 1724 and the interconnection layer 1722. As a result, the peripheral circuit 1712 can be coupled to the DRAM cell 1724 through the interconnection layers 1716 and 1722 and the bonding layers 1720 and 1718, and the peripheral circuit 1712 and the DRAM cell 1724 can be coupled to the external circuit through the contact 1752 and the pad-out interconnection layer 1750. The contact pad 1754 and the contact 1752 may comprise a conductive material, including, but not limited to, W, Co, Cu, Al, silicides, or any combination thereof. In one example, the contact pad 1754 may comprise Al, and the contact 1752 may comprise W. In some implementations, the contact 1752 comprises a via surrounded by a dielectric spacer (e.g., comprising silicon oxide) to electrically separate the via from the substrate 1748. Depending on a thickness of the substrate 1748, the contact 1752 may be an ILV with a depth at a submicron level (e.g., between 10 nm and 1 μm), or a TSV with a depth at a micrometer level or tens-of-micrometer level (e.g., between 1 μm and 100 μm).

The above descriptions are merely particular implementations of the present disclosure, and the protection scope of the present disclosure is not limited to those. Any variation or replacement that may be readily figured out by those skilled in the art within the technical scope disclosed by the present disclosure shall be encompassed within the protection scope of the present disclosure. Therefore, the protection scope of the present disclosure shall be defined by the protection scope of the claims.

What is claimed is:

1. A method of forming a semiconductor structure, the method comprising:
forming a plurality of first trenches in a semiconductor base from a surface of the semiconductor base, wherein the plurality of first trenches extend along a first direction;
forming a plurality of gate structures in the plurality of first trenches;
forming a plurality of second trenches in the semiconductor base, wherein each of the plurality of second trenches is between two adjacent trenches of the plurality of first trenches, and the plurality of second trenches extend along the first direction; and
forming a plurality of isolation structures in the plurality of second trenches.

2. The method of claim 1,
wherein, before forming the plurality of first trenches in the semiconductor base, the method further comprises:
disposing a mask layer on the surface of the semiconductor base and forming a plurality of openings in the mask layer, wherein forming the plurality of first trenches in the semiconductor base comprises: forming the plurality of first trenches by etching the semiconductor base through the plurality of openings of the mask layer,
wherein, after forming the plurality of gate structures in the plurality of first trenches and before forming the plurality of second trenches in the semiconductor base, the method further comprises:
forming a plurality of insulation filling structures, wherein each of the plurality of insulation filling structures is within one of the plurality of first trenches and one of the plurality of openings that are connected together, and wherein a portion of an insulation filling structure within a corresponding opening is defined as a first portion of the insulation filling structure;
removing at least a first sublayer between two adjacent insulation filling structures of the plurality of insulation filling structures, wherein the first sublayer comprises at least one part of the mask layer;
forming an isolation layer that covers the plurality of insulation filling structures and the surface of the semiconductor base; and
etching the semiconductor base along a target direction using a first etching process to form a plurality of barrier portions and a plurality of third trenches, the target direction being perpendicular to the first direction, wherein the target direction is defined as being from a first side of the semiconductor base facing the isolation layer to a second side of the semiconductor base facing away from the isolation layer, wherein each of the plurality of barrier portions comprises at least one part of the first portion and the isolation layer around the first portion that remains during the first etching process, and each of the plurality of third trenches is between two adjacent barrier portions of the plurality of barrier portions and exposes a corresponding portion of the surface of the semiconductor base, and
wherein forming the plurality of second trenches in the semiconductor base comprises:
etching the semiconductor base along the target direction by third trenches using a second etching process to form the plurality of second trenches.

3. The method of claim 2, wherein forming the isolation layer comprises:
forming a first dielectric layer and a second dielectric layer sequentially, wherein a material of the first dielectric layer is different from a material of the second dielectric layer.

4. The method of claim 3, wherein the material of the first dielectric layer comprises silicon nitride, and the material of the second dielectric layer comprises oxide.

5. The method of claim 2, wherein disposing the mask layer on the surface of the semiconductor base comprises:
forming the first sublayer on the surface of the semiconductor base, wherein a material of the first sublayer comprises oxide or silicon nitride.

6. The method of claim 2, wherein disposing the mask layer on the surface of the semiconductor base comprises:
forming a second sublayer and the first sublayer sequentially on the surface of the semiconductor base, wherein a material of the first sublayer is different from a material of the second sublayer.

7. The fabrication method of claim 6, wherein the material of the first sublayer comprises silicon nitride, and the material of the second sublayer comprises oxide.

8. The method of claim 6, wherein disposing the mask layer on the surface of the semiconductor base semiconductor base further comprises:
forming a third sublayer and a fourth sublayer sequentially on the first sublayer, wherein the material of the first sublayer is same as a material of the fourth sublayer, the material of the first sublayer is different from a material of the third sublayer, and the third sublayer serves as a stop layer during removal of the fourth sublayer.

9. The method of claim 6, wherein disposing the mask layer on the surface of the semiconductor base further comprises:
semiconductor base forming a fifth sublayer and a sixth sublayer sequentially on the second sublayer, wherein the fifth sublayer and the sixth sublayer are between the second sublayer and the first sublayer, the material of the second sublayer is same as a material of the sixth sublayer, the material of the second sublayer is different from a material of the fifth sublayer, and the fifth sublayer serves as a stop layer during removal of the sixth sublayer.

10. The method of claim 1, further comprising:
forming a first insulation layer on inner walls of the first trenches, wherein first sub-trenches are formed as being surrounded within the first insulation layer; and
forming stop blocks at bottoms of the first sub-trenches to obtain second sub-trenches,
wherein forming the plurality of gate structures in the plurality of first trenches comprises:
forming a gate layer on sidewalls of the second sub-trenches, wherein a space is left between the gate layer and the surface of the semiconductor base.

11. The method of claim 10, wherein forming the plurality of gate structures in the plurality of first trenches further comprises:
performing oxidation treatment on the sidewalls of the second sub-trenches to form a gate insulation layer.

12. The method of claim 1, wherein forming the plurality of isolation structures in the plurality of second trenches comprises:
forming a second insulation layer on inner walls of the second trenches, wherein accommodation trenches are formed as being surrounded within the second insulation layer;
forming isolation pillars in the accommodation trenches; and
filling the accommodation trenches with an insulation material to cover the isolation pillars.

13. The method of claim 1, wherein forming the plurality of isolation structures in the plurality of second trenches comprises:
filling the second trenches with an insulation material to form the isolation structures comprising air gaps.

14. A semiconductor structure, comprising:
a plurality of gate filling structures extending along a first direction;
a plurality of isolation structures each between two adjacent gate filling structures of the plurality of gate filling structures, wherein the plurality of isolation structures extend along the first direction, and an arrangement direction of the plurality of isolation structures and the plurality of gate filling structures is a second direction; and
a plurality of semiconductor pillars each between a corresponding isolation structure and a corresponding gate filling structure, wherein the plurality of semiconductor pillars extend along a third direction that intersects a first reference plane, and the first direction and the second direction are in the first reference plane,
wherein a length of an isolation structure along the first direction is smaller than a length of a gate filling structure along the first direction.

15. The semiconductor structure of claim 14, wherein the first direction and the third direction are in a second reference plane, an orthographic projection of the isolation structure on the second reference plane is a first orthographic projection, and an orthographic projection of the gate filling structure on the second reference plane is a second orthographic projection, and
wherein two ends of the first orthographic projection are between two ends of the second orthographic projection along the first direction.

16. The semiconductor structure of claim 14, wherein the semiconductor structure has a core area and an edge area, and
wherein the gate filling structure is in the core area and the edge area, and the isolation structure is in the core area.

17. The semiconductor structure of claim 14, wherein distances between the isolation structure and the two adjacent gate filling structures are equal along the second direction.

18. The semiconductor structure of claim 14, wherein a difference in distances between the isolation structure and the two adjacent gate filling structures along the second direction is no greater than 10 nm.

19. The semiconductor structure of claim 14, wherein the gate filling structure comprises a stop structure and a gate structure that are stacked along the third direction, wherein the stop structure comprises a stop block and a first insulation layer that is between the stop block and the semiconductor pillar, and the gate structure comprises a gate layer and a gate insulation layer that is between the gate layer and the semiconductor pillar; and
distances between the isolation structure and the gate insulation layers in the two adjacent gate filling structures are equal along the second direction.

20. A memory system, comprising:
a semiconductor structure comprising:
a plurality of gate filling structures extending along a first direction;
a plurality of isolation structures each between two adjacent gate filling structures of the plurality of gate filling structures, wherein the plurality of isolation structures extend along the first direction, and an arrangement direction of the plurality of isolation structures and the plurality of gate filling structures is a second direction; and
a plurality of semiconductor pillars each between a corresponding isolation structure and a corresponding gate filling structure, wherein the plurality of semiconductor pillars extend along a third direction that intersects a first reference plane, and the first direction and the second direction are in the first reference plane,
wherein a length of an isolation structure along the first direction is smaller than a length of a gate filling structure along the first direction; and
a controller coupled to the semiconductor structure and configured to control the semiconductor structure.
